(19) United States
(12) Patent Application Publication
(10) Pub. No.: US 2024/0018381 A1
(43) Pub. Date: Jan. 18, 2024

(54) NANOIMPRINT LITHOGRAPHY RESIN COMPOSITION

(71) Applicant: ILLUMINA CAMBRIDGE LIMITED, Cambridge (GB)

(72) Inventors: Alexandra Szemjonov, Cambridge (GB); Alexandre Richez, Cambourne (GB)

(21) Appl. No.: 18/343,713

(22) Filed: Jun. 28, 2023

Related U.S. Application Data
(60) Provisional application No. 63/357,501, filed on Jun. 30, 2022.

(51) Int. Cl. C09D 163/00; C08G 59/36; C08G 59/32; C08G 59/68; C09D 7/63; B01L 3/00

(52) U.S. Cl. CPC C09D 163/00; C08G 59/36; C08G 59/3281; C08G 59/688; C09D 7/63; B01L 3/502761; B01L 2300/0654; B01L 2200/0647

(57) ABSTRACT

An example nanoimprint lithography (NIL) resin composition includes a total of three monomers, wherein two of the three monomers are selected from the group consisting of two different epoxy substituted silsesquioxane monomers; two different epoxy substituted cyclosiloxane monomers; and two different non-organosilicon epoxy monomers. A third of the three monomers is a fluorinated monomer that is present in an amount ranging from about from 0.5 mass % to about 4 mass %, based on a total solids content of the NIL resin composition. The NIL resin also includes a photoinitiator and a solvent.

### CROSS-REFERENCE TO RELATED APPLICATION

This application claims the benefit of U.S. Provisional Application Ser. No. 63/357,501, filed Jun. 30, 2022, the contents of which is incorporated by reference herein in its entirety.

### REFERENCE TO SEQUENCE LISTING

The Sequence Listing submitted herewith is hereby incorporated by reference in its entirety. The name of the file is ILI248B_IP-2374-US_Sequence_Listing.xml, the size of the file is 13,697 bytes, and the date of creation of the file is Jun. 17, 2023.

### BACKGROUND

Nanoimprinting technology enables the economic and effective production of nanostructures. Nanoimprint lithography employs direct mechanical deformation of a material by a stamp having nanostructures. The material is cured while the stamp is in place to lock the shape of the nanostructures in the material. Nanoimprint lithography has been used to manufacture patterned substrates, and, in many instances, the nanoimprinted material becomes a permanent feature or component of the patterned substrate.

### SUMMARY

The nanoimprint lithography resins disclosed herein include a fluorinated monomer. The fluorinated monomer has limited miscibility with the other monomers (e.g., silsesquioxane monomers, cyclosiloxane monomers, or non-organosilicon epoxy monomers) in the resin composition, and thus it tends to migrate to the surface of the resin when it is in the solid state, e.g., when the solvent has been removed after it has been coated. The presence of the fluorinated monomer at the surface of the coated resin lowers its surface energy. The lower surface energy contributes i) to the resin's ability to replicate a pattern of an imprinting apparatus (e.g., working stamp, template, or mold) with high fidelity and ii) to the resin's ability to readily release the imprinting apparatus, thus avoiding fouling of the imprinting apparatus. Maintaining a clean and non-fouled imprinting apparatus should, in turn, lead to the imprinting apparatus having a longer lifetime.

The fluorinated monomer(s) are also unexpectedly compatible with polymeric hydrogel attachment, primer grafting, clustering, and sequencing. In particular, the fluorinated monomers are able to strongly bind the polymeric hydrogel and survive multiple sequencing cycles.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIGS. 1A through 1E are schematic perspective views which together depict an example of a method, where FIG. 1A depicts a substrate, FIG. 1B depicts an example of a NIL resin composition deposited on the substrate and a working stamp used to imprint the NIL resin composition, FIG. 1C depicts the imprinted and cured resin composition, FIG. 1D depicts a polymeric hydrogel introduced into the depression of the imprinted and cured resin composition, and FIG. 1E depicts primers grafted to the polymeric hydrogel;

FIG. 2 is a schematic, cross-sectional view taken along line 2-2 of the flow cell surface of FIG. 1E;

FIG. 3 is a graph depicting the mean water contact angle (mean WCA) (°, Y axis) for imprints generated with example resins and comparative example resins;

FIG. 4 is a graph depicting the cycle intensity (called intensity) (arbitrary units, Y axis) versus the cycle number (X axis) for one cycle of sequencing-by-synthesis using an example of a flow cell disclosed herein;

FIG. 5A and FIG. 5B are optical microscopy images of (FIG. 5A) a tile of a flow cell during a sequencing cycle using blue illumination and (FIG. 5B) an enlarged compilation of the highlighted areas of FIG. 5A; and

FIG. 6A and FIG. 6B are optical microscopy images of (FIG. 6A) a tile of a flow cell during a sequencing cycle using violet illumination and (FIG. 6B) an enlarged compilation of the highlighted areas of FIG. 6A.

### DETAILED DESCRIPTION

With nanoimprint lithography, a resin composition (including polymerizable multi-functional monomers) is deposited on a substrate. The deposited resin composition is patterned with an imprinting apparatus, which is pressed onto the resin surface. The resin composition deforms to fill the imprinting apparatus pattern. While the imprinting apparatus is still in contact with the resin composition, polymerization of the resin composition is initiated by exposure to light or heat, and the resin is cured. After the resin composition is sufficiently crosslinked such that it is no longer able to flow, the imprinting apparatus is peeled away from the surface, leaving behind an imprinted resin surface. When nanoimprinting is successful, features of the imprinting apparatus are transferred to the cured resin. In some examples, the features (e.g., depressions or trenches) can then be functionalized with surface chemistry that enables fluorescent-based sequencing, analyte detection, etc.

In the examples disclosed herein, the resin composition includes a fluorinated monomer that has limited miscibility with the other monomers in the resin composition, and thus can function as a surface additive. In particular, the fluorinated monomer tends to migrate to the surface of the resin when it is in the solid state, which lowers its surface energy. The lower surface energy contributes to the resin's ability i) to replicate an imprinting apparatus pattern with high fidelity and ii) to readily release the imprinting apparatus, thus keeping the imprinting apparatus clean.

### Definitions

It is to be understood that terms used herein will take on their ordinary meaning in the relevant art unless specified otherwise. Several other terms are used herein. The meanings of these additional terms are set forth below.

The singular forms “a”, “an”, and “the” include plural referents unless the context clearly dictates otherwise.

The terms comprising, including, containing and various forms of these terms are synonymous with each other and are meant to be equally broad.

The terms top, bottom, lower, upper, on, adjacent, etc. are used herein to describe the flow cell and/or the various components of the flow cell. It is to be understood that these directional terms are not meant to imply a specific orientation, but are used to designate relative orientation between components. The use of directional terms should not be interpreted to limit the examples disclosed herein to any specific orientation(s).

The terms first, second, etc. also are not meant to imply a specific orientation or order, but rather are used to distinguish one component from another.

It is to be understood that the ranges provided herein include the stated range and any value or sub-range within the stated range, as if such values or sub-ranges were explicitly recited. For example, a range of about 400 nm to about 1 μm (1000 nm), should be interpreted to include not only the explicitly recited limits of about 400 nm to about 1 μm, but also to include individual values, such as about 708 nm, about 945.5 nm, etc., and sub-ranges, such as from about 425 nm to about 825 nm, from about 550 nm to about 940 nm, etc. Furthermore, when “about” and/or “substantially” are/is utilized to describe a value, they are meant to encompass minor variations (up to +/−10%) from the stated value.

An “acrylamide” is a functional group with the structure

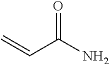

where each H may alternatively be an alkyl, an alkylamino, an alkylamido, an alkylthio, an aryl, a glycol, and optionally substituted variants thereof. Examples of monomers including an acrylamide functional group include azido acetamido pentyl acrylamide:

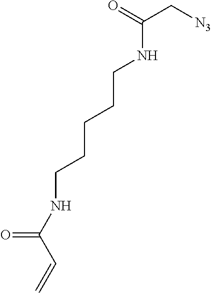 [SMILES: C=CC(=O)NCCCCCNC(=O)CN=[N+]=[N-]]

### and N-isopropylacrylamide:

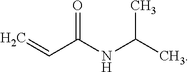

Other acrylamide monomers may be used, some examples of which are set forth herein.

As used herein the term “acrylate” refers to a “CH₂═CHCOO—” functional group

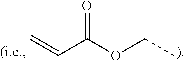

Acrylates include substituted variations thereof (e.g., methacrylate is an example of an acrylate).

An “aldehyde,” as used herein, is an organic compound containing a functional group with the structure —CHO, which includes a carbonyl center (i.e., a carbon double-bonded to oxygen) with the carbon atom also bonded to hydrogen and an R group, such as an alkyl or other side chain. The general structure of an aldehyde is:

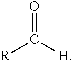

As used herein, “alkyl” refers to a straight or branched hydrocarbon chain that is fully saturated (i.e., contains no double or triple bonds). The alkyl group may have 1 to 20 carbon atoms. Example alkyl groups include methyl, ethyl, propyl, isopropyl, butyl, isobutyl, tertiary butyl, pentyl, hexyl, and the like. As an example, the designation “C1-C4 alkyl” indicates that there are one to four carbon atoms in the alkyl chain, i.e., the alkyl chain is selected from the group consisting of methyl, ethyl, propyl, iso-propyl, n-butyl, isobutyl, sec-butyl, and t-butyl. An alkyl may be substituted or unsubstituted. An example of a substituted alkyl is a haloalkyl, or an alkyl substituted with a halogen.

As used herein, “alkylamino” refers to an alkyl group in which one or more of the hydrogen atoms are replaced by an amino group, where the amino group refers to an —NRₐR_{b} group, where Rₐ and R_{b} are each independently selected from a C1-C6 alkyl, C2-C6 alkenyl, C2-C6 alkynyl, C3-C7 carbocycle, C6-C10 aryl, a 5-10 membered heteroaryl, and a 5-10 membered heterocycle.

As used herein, “alkylamido” refers to an alkyl group in which one or more of the hydrogen atoms are replaced by a C-amido group or an N-amido group. A “C-amido” group refers to a “—C(═O)N(RₐR_{b})” group in which Rₐ and R_{b} can independently be selected from the group consisting of alkyl, alkenyl, alkynyl, cycloalkyl, cycloalkenyl, cycloalkynyl, aryl, heteroaryl, heteroalicycle, aralkyl, or (heteroalicyclic)alkyl. An “N-amido” group refers to a “RC(═O)N(Rₐ)—” group in which R and Rₐ can independently be selected from the group consisting of alkyl, alkenyl, alkynyl, cycloalkyl, cycloalkenyl, cycloalkynyl, aryl, heteroaryl, heteroalicycle, aralkyl, or (heteroalicyclic)alkyl. Any alkylamido may be substituted or unsubstituted.

As used herein, “alkylthio” refers to RS—, in which R is an alkyl. The alkylthio can be substituted or unsubstituted.

As used herein, “alkene” or “alkenyl” refers to a straight or branched hydrocarbon chain containing one or more double bonds. The alkenyl group may have 2 to 20 carbon atoms. Example alkenyl groups include ethenyl, propenyl, butenyl, pentenyl, hexenyl, and the like.

As used herein, “alkyne” or “alkynyl” refers to a straight or branched hydrocarbon chain containing one or more triple bonds. The alkynyl group may have 2 to 20 carbon atoms.

An “amine” or “amino” functional group refers to an —NRₐR_{b} group, where Rₐ and R_{b} are each independently selected from hydrogen

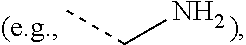

C1-C6 alkyl, C2-C6 alkenyl, C2-C6 alkynyl, C3-C7 carbocycle, C6-C10 aryl, 5-10 membered heteroaryl, and 5-10 membered heterocycle, as defined herein.

As used herein, “aralkyl” and “aryl(alkyl)” refer to an aryl group connected, as a substituent, via a lower alkylene group. The lower alkylene and aryl group of an aralkyl may be substituted or unsubstituted. Examples include but are not limited to benzyl, 2-phenylalkyl, 3-phenylalkyl, and naphthylalkyl.

The term “aryl” refers to an aromatic ring or ring system (i.e., two or more fused rings that share two adjacent carbon atoms) containing only carbon in the ring backbone. When the aryl is a ring system, every ring in the system is aromatic. The aryl group may have 6 to 18 carbon atoms. Examples of aryl groups include phenyl, naphthyl, azulenyl, and anthracenyl. Any aryl may be a heteroaryl, with at least one heteroatom, that is, an element other than carbon (e.g., nitrogen, oxygen, sulfur, etc.), in ring backbone.

As used herein, the term “attached” refers to the state of two things being joined, fastened, adhered, connected or bound to each other, either directly or indirectly. For example, a nucleic acid strand can be attached to a polymer hydrogel by a covalent or non-covalent bond. A covalent bond is characterized by the sharing of pairs of electrons between atoms. A non-covalent bond is a physical bond that does not involve the sharing of pairs of electrons and can include, for example, hydrogen bonds, ionic bonds, van der Waals forces, hydrophilic interactions and hydrophobic interactions.

An “azide” or “azido” functional group refers to —N₃.

As used herein, “carbocycle” means a non-aromatic cyclic ring or ring system containing only carbon atoms in the ring system backbone. When the carbocycle is a ring system, two or more rings may be joined together in a fused, bridged or spiro-connected fashion. Carbocycles may have any degree of saturation, provided that at least one ring in a ring system is not aromatic. Thus, carbocycles include cycloalkyls, cycloalkenyls, and cycloalkynyls. The carbocycle group may have 3 to 20 carbon atoms. Examples of carbocycle rings include cyclopropyl, cyclobutyl, cyclopentyl, cyclohexyl, cyclohexenyl, 2,3-dihydro-indene, bicyclo[2.2.2]octanyl, adamantyl, and spiro[4.4]nonanyl. Any of the carbocycles may be heterocycles, with at least one heteroatom in ring backbone.

As used herein, “cycloalkyl” refers to a completely saturated (no double or triple bonds) mono- or multi-cyclic hydrocarbon ring system. When composed of two or more rings, the rings may be joined together in a fused fashion. Cycloalkyl groups can contain 3 to 10 atoms in the ring(s). In some examples, cycloalkyl groups can contain 3 to 8 atoms in the ring(s). A cycloalkyl group may be unsubstituted or substituted. Example cycloalkyl groups include cyclopropyl, cyclobutyl, cyclopentyl, cyclohexyl, cycloheptyl, and cyclooctyl.

As used herein, “cycloalkenyl” or “cycloalkene” means a carbocycle ring or ring system having at least one double bond, wherein no ring in the ring system is aromatic. Examples include cyclohexenyl or cyclohexene and norbornenyl or norbornene.

As used herein, “cycloalkynyl” or “cycloalkyne” means a carbocycle ring or ring system having at least one triple bond, wherein no ring in the ring system is aromatic. An example is cyclooctyne. Another example is bicyclononyne. Still another example is dibenzocyclooctyne (DBCO).

The term “depositing,” as used herein, refers to any suitable application technique, which may be manual or automated, and, in some instances, results in modification of the surface properties. Depositing may be performed using vapor deposition techniques, coating techniques, grafting techniques, or the like. Some specific examples include chemical vapor deposition (CVD), spray coating (e.g., ultrasonic spray coating), spin coating, dunk or dip coating, doctor blade coating, puddle dispensing, flow through coating, aerosol printing, screen printing, microcontact printing, inkjet printing, or the like.

As used herein, the term “depression” refers to a discrete concave feature in a patterned resin having a surface opening that is at least partially surrounded by interstitial region(s) of the cured resin. Depressions can have any of a variety of shapes at their opening in a surface including, as examples, round, elliptical, square, polygonal, star shaped (with any number of vertices), etc. The cross-section of a depression taken orthogonally with the surface can be curved, square, polygonal, hyperbolic, conical, angular, etc. The depression may also have more complex architectures, such as ridges, step features, etc. Depressions are one example of the features that can be formed using nanoimprint lithography. Another example of such a feature is a trench/trough.

The term “each,” when used in reference to a collection of items, is intended to identify an individual item in the collection, but does not necessarily refer to every item in the collection. Exceptions can occur if explicit disclosure or context clearly dictates otherwise.

The term “epoxy” as used herein refers to

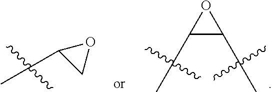

As used herein, the term “flow cell” is intended to mean a vessel having a flow channel where a reaction can be carried out, an inlet for delivering reagent(s) to the flow channel, and an outlet for removing reagent(s) from the flow channel. In some examples, the flow cell enables the detection of the reaction that occurs in the flow channel. For example, the flow cell may include one or more transparent surfaces allowing for the optical detection of arrays, optically labeled molecules, or the like within the flow channel.

As used herein, a “flow channel” or “channel” may be an area defined between two bonded components, which can selectively receive a liquid sample. In examples disclosed herein, the flow channel may be defined between a patterned substrate and a lid, and thus may be in fluid communication with one or more depressions defined in the patterned substrate or resin. The flow channel may also be defined between two patterned substrate surfaces that are bonded together.

As used herein, “heteroalicyclic” or “heteroalicycle” refers to three-, four-, five-, six-, seven-, eight-, nine-, ten-, up to 18-membered monocyclic, bicyclic, and tricyclic ring system wherein carbon atoms together with from 1 to 5 heteroatoms constitute said ring system. A heteroalicyclic ring system may optionally contain one or more unsaturated bonds situated in such a way, however, that a fully delocalized pi-electron system does not occur throughout all the rings. The heteroatoms are independently selected from oxygen, sulfur, and nitrogen. A heteroalicyclic ring system may further contain one or more carbonyl or thiocarbonyl functionalities, so as to make the definition include oxo-systems and thio-systems such as lactams, lactones, cyclic imides, cyclic thioimides, and cyclic carbamates. The rings may be joined together in a fused fashion. Additionally, any nitrogens in a heteroalicyclic may be quaternized. Heteroalicycle or heteroalicyclic groups may be unsubstituted or substituted. Examples of such “heteroalicyclic” or “heteroalicycle” groups include 1,3-dioxin, 1,3-dioxane, 1,4-dioxane, 1,2-dioxolane, 1,3-dioxolane, 1,4-dioxolane, 1,3-oxathiane, 1,4-oxathiin, 1,3-oxathiolane, 1,3-dithiole, 1,3-dithiolane, 1,4-oxathiane, tetrahydro-1,4-thiazine, 2H-1,2-oxazine, maleimide, succinimide, barbituric acid, thiobarbituric acid, dioxopiperazine, hydantoin, dihydrouracil, trioxane, hexahydro-1,3,5-triazine, imidazoline, imidazolidine, isoxazoline, isoxazolidine, oxazoline, oxazolidine, oxazolidinone, thiazoline, thiazolidine, morpholine, oxirane, piperidine N-oxide, piperidine, piperazine, pyrrolidine, pyrrolidone, pyrrolidione, 4-piperidone, pyrazoline, pyrazolidine, 2-oxopyrrolidine, tetrahydropyran, 4H-pyran, tetrahydrothiopyran, thiamorpholine, thiamorpholine sulfoxide, thiamorpholine sulfone, and their benzo-fused analogs (e.g., benzimidazolidinone, tetrahydroquinoline, 3,4-methylenedioxyphenyl).

A “(heteroalicyclic)alkyl” refers to a heterocyclic or a heteroalicyclic group connected, as a substituent, via a lower alkylene group. The lower alkylene and heterocycle or a heterocycle of a (heteroalicyclic)alkyl may be substituted or unsubstituted. Examples include but are not limited tetrahydro-2H-pyran-4-yl)methyl, (piperidin-4-yl)ethyl, (piperidin-4-yl)propyl, (tetrahydro-2H-thiopyran-4-yl)methyl, and (1,3-thiazinan-4-yl)methyl.

As used herein, “heteroaryl” refers to an aromatic ring or ring system (i.e., two or more fused rings that share two adjacent atoms) that contain(s) one or more heteroatoms, that is, an element other than carbon, including but not limited to, nitrogen (N), oxygen (O) and sulfur (S), in the ring backbone. When the heteroaryl is a ring system, every ring in the system is aromatic. The heteroaryl group may have 5-18 ring members.

As used herein, “heterocycle” means a non-aromatic cyclic ring or ring system containing at least one heteroatom in the ring backbone. Heterocycles may be joined together in a fused, bridged or spiro-connected fashion. Heterocycles may have any degree of saturation provided that at least one ring in the ring system is not aromatic. In the ring system, the heteroatom(s) may be present in either a non-aromatic or aromatic ring. The heterocycle group may have 3 to 20 ring members (i.e., the number of atoms making up the ring backbone, including carbon atoms and heteroatoms). In some examples, the heteroatom(s) are O, N, or S.

The term “hydrazine” or “hydrazinyl” as used herein refers to a —NHNH₂ group.

As used herein, the term “hydrazone” or “hydrazonyl” as used herein refers to a

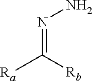

group in which Rₐ and R_{b} are each independently selected from hydrogen, C1-6 alkyl, C2-6 alkenyl, C2-6 alkynyl, C3-7 carbocyclyl, C6-10 aryl, 5-10 membered heteroaryl, and 5-10 membered heterocyclyl, as defined herein.

As used herein, “hydroxy” or “hydroxyl” refers to an —OH group.

As used herein, an “initiator” is a molecule that undergoes a reaction upon absorption of radiation or heat or upon exposure to free radicals, thereby producing a reactive species. Initiators are capable of initiating or catalyzing chemical reactions that result in changes in the solubility and/or physical properties of formulations. A “cationic initiator” or “photoacid generator” (PAG) is a molecule that becomes acidic upon exposure to radiation or to free radicals. PAGs generally undergo proton photodissociation irreversibly. A “free radical initiator” is a molecule that generates a radical species upon exposure to radiation or heat and that promotes radical reactions.

As used herein, the term “interstitial region” refers to an area on a surface (e.g., of a cured patterned resin) that separates depressions or other features. For example, an interstitial region can separate one feature of an array from another feature of the array. The two features that are separated from each other can be discrete, i.e., lacking physical contact with each other. In another example, an interstitial region can separate a first portion of a feature from a second portion of a feature. In many examples, the interstitial region is continuous whereas the features are discrete, for example, as is the case for a plurality of depressions defined in an otherwise continuous surface. In other examples, the interstitial regions and the features are discrete, for example, as is the case for a plurality of trenches separated by respective interstitial regions. The separation provided by an interstitial region can be partial or full separation. Interstitial regions may have a surface material that differs from the surface material of the features. For example, features of an array can have an amount or concentration of a polymeric hydrogel and primer(s) that exceeds the amount or concentration present at the interstitial regions. In some examples, the polymeric hydrogel and primer(s) may not be present at the interstitial regions.

As used herein, the phrase “limited miscibility” means that the fluorinated monomer and the other monomers do not fully mix in at least some proportions. The limited miscibility may be evaluated qualitatively. For example, R-ray photoelectron spectroscopy (XPS), energy-dispersive spectroscopy (EDS), or time-of-flight secondary ion mass spectroscopy (TOF-SIMS) may be used to evaluate the accumulation of fluorinated compounds at different depths of the coating. The more pronounced the accumulation, the more limited the miscibility.

“Nitrile oxide,” as used herein, means a “RₐC≡N+O” group in which Rₐ is defined herein. Examples of preparing nitrile oxide include in situ generation from aldoximes by treatment with chloramide-T or through action of base on imidoyl chlorides [RC(Cl)═NOH] or from the reaction between hydroxylamine and an aldehyde.

“Nitrone,” as used herein, means a

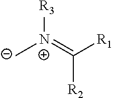

group in which R₁, R₂, and R₃ may be any of the Rₐ and R_{b} groups defined herein.

As used herein, a “nucleotide” includes a nitrogen containing heterocyclic base, a sugar, and one or more phosphate groups. Nucleotides are monomeric units of a nucleic acid sequence. In RNA (ribonucleic acid), the sugar is a ribose, and in DNA (deoxyribonucleic acid), the sugar is a deoxyribose, i.e. a sugar lacking a hydroxyl group that is present at the 2′ position in ribose. The nitrogen containing heterocyclic base (i.e., nucleobase) can be a purine base or a pyrimidine base. Purine bases include adenine (A) and guanine (G), and modified derivatives or analogs thereof. Pyrimidine bases include cytosine (C), thymine (T), and uracil (U), and modified derivatives or analogs thereof. The C-1 atom of deoxyribose is bonded to N-1 of a pyrimidine or N-9 of a purine. A nucleic acid analog may have any of the phosphate backbone, the sugar, or the nucleobase altered. Examples of nucleic acid analogs include, for example, universal bases or phosphate-sugar backbone analogs, such as peptide nucleic acid (PNA).

As used herein, the “primer” is defined as a single stranded nucleic acid sequence (e.g., single strand DNA). Some primers, which may be referred to as amplification primers, serve as a starting point for template amplification and cluster generation. The 5′ terminus of these primers may be modified to allow a coupling reaction with a functional group of the polymeric hydrogel. Other primers, which may be referred to as sequencing primers, serve as a starting point for DNA synthesis. The primer length can be any number of bases long and can include a variety of non-natural nucleotides. In an example, the sequencing primer is a short strand, ranging from 10 to 60 bases, or from 20 to 40 bases.

The term “resin composition” refers to any of the monomer mixtures set forth herein. The resin composition may also include one or more initiators as defined herein and a solvent.

A “spacer layer,” as used herein refers to a material that bonds two components together. In some examples, the spacer layer can be a radiation-absorbing material that aids in bonding, or can be put into contact with a radiation-absorbing material that aids in bonding. The spacer layer may be present in a bonding region, e.g., an area on a substrate that is to be bonded to another material, which may be, as examples, a spacer layer, a lid, another substrate, etc., or combinations thereof (e.g., the spacer layer and a lid). The bond that is formed at the bonding region may be a chemical bond (as described above), or a mechanical bond (e.g., using a fastener, etc.).

A “thiol” functional group refers to —SH.

As used herein, the terms “tetrazine” and “tetrazinyl” refer to six-membered heteroaryl group comprising four nitrogen atoms. Tetrazine can be optionally substituted.

“Tetrazole,” as used herein, refer to five-membered heterocyclic group including four nitrogen atoms. Tetrazole can be optionally substituted.

The term “ultraviolet light curable” means polymerization or polymerization and crosslinking of the resin composition is/are initiated by exposure to ultraviolet light, i.e., radiation with wavelengths ranging from about 280 nm to about 400 nm.

Resin Composition

The nanoimprint lithography (NIL) resin compositions disclosed herein include a total of three monomers, wherein: two of the three monomers are selected from the group consisting of two different epoxy substituted silsesquioxane monomers; two different epoxy substituted cyclosiloxane monomers; and two different non-organosilicon epoxy monomers; and a third of the three monomers is a fluorinated monomer that is present in an amount ranging from about from 0.5 mass % to about 4 mass %, based on a total solids content of the NIL resin composition; a photoinitiator; and a solvent.

Each of the NIL resin compositions disclosed herein includes a total of three monomers. By “a total of three monomers,” it is meant that the monomers in the resin composition consist of two different epoxy substituted silsesquioxane monomers or two different epoxy substituted cyclosiloxane monomers or two different non-organosilicon epoxy monomers and the fluorinated monomer(s). The fluorinated monomer is a class of organic monomers that contain fluorine, and it is to be understood that any single fluorinated monomer or any combination of fluorinated monomers may make up the third of the three monomers. The NIL resin does not include monomers other than the two different epoxy substituted silsesquioxane monomers or two different epoxy substituted cyclosiloxane monomers or two different non-organosilicon epoxy monomers and the fluorinated monomer(s).

In one example of the NIL resin composition, two different epoxy substituted polyhedral oligomeric silsesquioxane monomers are used. As used herein, the term “polyhedral oligomeric silsesquioxane” refers to a chemical composition that is a hybrid intermediate (e.g., RSiO_{1.5}) between that of silica (SiO₂) and silicone (R₂SiO). Some polyhedral oligomeric silsesquioxanes are commercially available as POSS® from Hybrid Plastics. An example of a polyhedral oligomeric silsesquioxane may be that described in Kehagias et al., Microelectronic Engineering 86 (2009), pp. 776-778, which is incorporated by reference in its entirety. In the examples disclosed herein, the composition is an organosilicon compound with the chemical formula [RSiO_{3/2}]ₙ, where the R groups can be the same or different, as long as one of the R groups is an epoxy. Other example R groups include azide/azido, a thiol, a poly(ethylene glycol), a norbornene, a tetrazine, acrylates, and/or methacrylates, or further, for example, alkyl, aryl, alkoxy, and/or haloalkyl groups.

In an example, the two of the three monomers are the two different epoxy substituted silsesquioxane monomers; and the two different epoxy substituted silsesquioxane monomers consist of epoxycyclohexylethyl polysilsesquioxane:

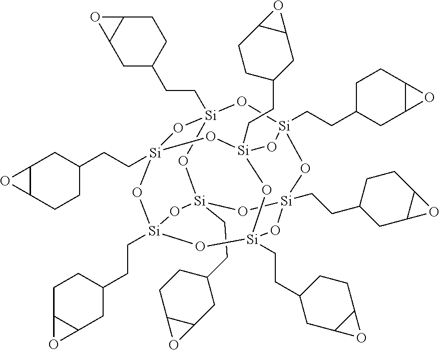 [SMILES: C1CC2OC2CC1CC[Si]12O[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1]

and glycidyl polysilsesquioxane

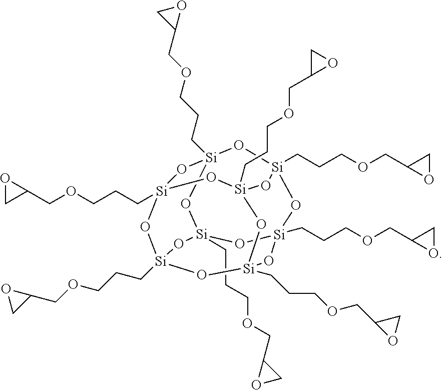 [SMILES: C(COCC1CO1)C[Si]12O[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](CCCOCC2CO2)(O4)O1]

The two different epoxy substituted silsesquioxane monomers may be present at a mass ratio ranging from about 3:7 to about 7:3. In one specific example, the mass ratio of the epoxycyclohexylethyl polysilsesquioxane and the glycidyl polysilsesquioxane is 1.5:1.

In another example of the NIL resin composition, two different epoxy substituted cyclosiloxane monomers are used. As used herein, the term “epoxy substituted cyclosiloxane” refers to a monomer having three or more repeating units of silicon and oxygen in a closed loop or ring, where the ring is functionalized with an epoxy-containing functional group. Within the ring, the Si:O ratio is 1:1.

In one specific example, the two of the three monomers are the two different epoxy substituted cyclosiloxane monomers; and the two different epoxy substituted cyclosiloxane monomers consist of epoxycyclohexyl tetramethylcyclotetrasiloxane:

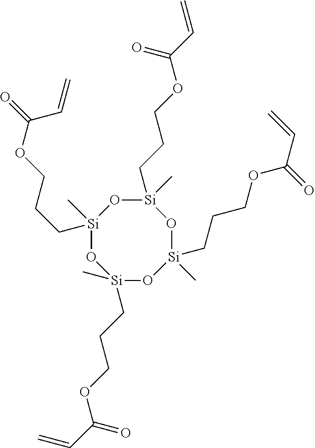 [SMILES: C=CC(=O)OCCC[Si]1(C)O[Si](C)(CCCOC(=O)C=C)O[Si](C)(CCCOC(=O)C=C)O[Si](C)(CCCOC(=O)C=C)O1]

and glycidyl cyclotetrasiloxane:

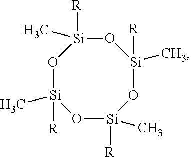

where R is:

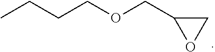

The two different epoxy substituted cyclosiloxane monomers may be present at a mass ratio ranging from about 3:7 to about 7:3. In one specific example, the mass ratio of the epoxycyclohexyl tetramethylcyclotetrasiloxane and the glycidyl cyclotetrasiloxane is 1.5:1.

In still another example of the NIL resin composition, and two different non-organosilicon epoxy monomers are used. The non-organosilicon epoxy monomers are epoxy monomers that do not include the O—Si—O linkages.

In one specific example, the two of the three monomers are the two different non-organosilicon epoxy monomers; and the two different non-organosilicon epoxy monomers are independently selected from the group consisting of:
i) trimethylolpropane triglycidyl ether:

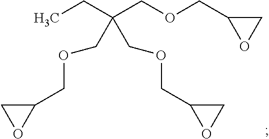 [SMILES: CCC(COCC1CO1)(COCC1CO1)COCC1CO1]

ii) 3,4-epoxycyclohexylmethyl-3,4-epoxycyclo-hexanecarboxylate:

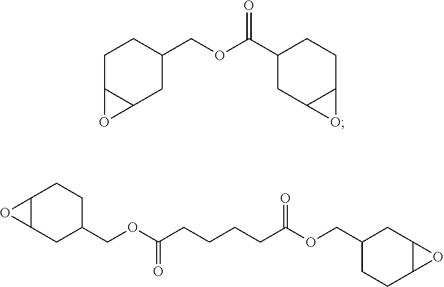 [SMILES: O=C(OCC1CCC2OC2C1)C1CCC2OC2C1 ; O=C(CCCCC(=O)OCC1CCC2OC2C1)OCC1CCC2OC2C1]

iii) bis((3,4-epoxycyclohexyl)methyl) adipate:
iv) 4-vinyl-1-cyclohexene 1,2-epoxide:

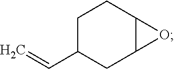

v) vinylcyclohexene dioxide:

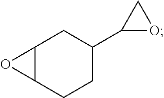

vi) 4,5-epoxytetrahydrophthalic acid diglycidylester:

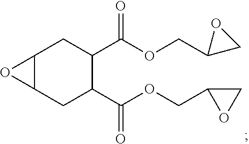 [SMILES: O=C(OCC1CO1)C1CC2OC2CC1C(=O)OCC1CO1]

vii) 1,2-epoxyhexadecane:

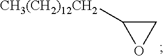

viii) poly(ethylene glycol) diglycidylether:

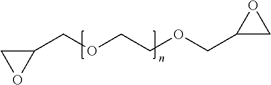

(wherein n ranges from 1 to 100);
ix) pentaerythritol glycidyl ether:

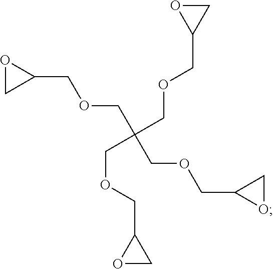 [SMILES: C(OCC(COCC1CO1)(COCC1CO1)COCC1CO1)C1CO1]

x) diglycidyl 1,2-cyclohexanedicarboxylate:

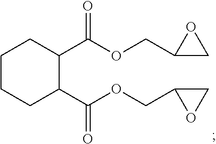 [SMILES: O=C(OCC1CO1)C1CCCCC1C(=O)OCC1CO1]

xi) tetrahydrophthalic acid diglycidyl ester:

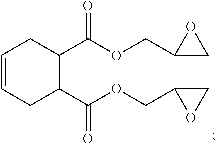 [SMILES: O=C(OCC1CO1)C1CC=CCC1C(=O)OCC1CO1]

xii) 1,2-epoxy-3-phenoxypropane:

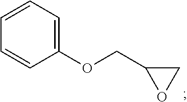 [SMILES: c1ccc(OCC2CO2)cc1]

and
xiii) glycidyl methacrylate:

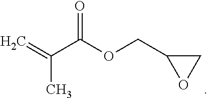

In one example, the two different non-organosilicon epoxy monomers are trimethylolpropane triglycidyl ether and 3,4-epoxycyclohexylmethyl-3,4-epoxycyclo-hexanecarboxylate. The two different non-organosilicon epoxy monomers may be present at a mass ratio ranging from about 4:1 to about 1:4. In one specific example, the mass ratio of the first non-organosilicon epoxy monomer and the second non-organosilicon epoxy monomer is 1:1.

In any of the NIL resin compositions, the total amount of the two different epoxy substituted silsesquioxane monomers or the two different epoxy substituted cyclosiloxane monomers or the two different non-organosilicon epoxy monomers ranges from about 61 mass % to less than 100 mass %, based on the total solids in the resin composition. The total amount of the two different monomers depends upon the other solids, e.g., the fluorinated monomer and the initiator(s), that are present in the NIL resin composition. In one example, the two different monomers together make up from about 67 mass % to about 90 mass % of the total solids in the resin composition.

A third of the three monomers is a fluorinated monomer. Any fluorinated organic monomer that has limited miscibility with the epoxy-containing monomers may be used. As mentioned, the limited miscibility contributes to the migration of the fluorinated monomer(s) to the surface of the resin composition when it is in the solid state, which lowers the surface energy of the cured resin composition. Additionally, some of the fluorinated monomers have reactive groups (e.g., epoxy groups) that polymerize when exposed to ultraviolet (UV) light. Thus, in addition to being able to migrate to the surface of the resin composition, the reactive groups of the fluorinated monomers can react with each other or with reactive groups of the other monomers at or near the surface of the resin composition. The ability of the fluorinated monomer(s) to participate in polymerization and cross-linking increases the robustness of the cured resin composition.

The fluorinated monomer is selected from the group consisting of 2,2′-(2,2,3,3,4,4,5,5-octafluorohexane-1,6-diyl)bis(oxirane):

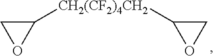

glycidyl 2,2,3,3,4,4,5,5-octafluoropentyl ether:

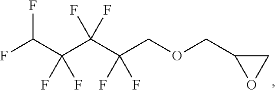 [SMILES: FC(F)C(F)(F)C(F)(F)C(F)(F)COCC1CO1]

glycidyl 2,2,3,3-tetrafluoropropyl ether:

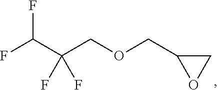 [SMILES: FC(F)C(F)(F)COCC1CO1]

(2,2,3,3,4,4,5,5,6,6,7,7,8,8,9,9,9-heptadecafluorononyl)oxirane:

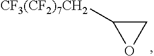

(2,2,3,3,4,4,5,5,6,6,7,7,7-tridecafluoroheptyl)oxirane:

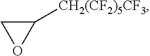

2,2,3,3,4,4,5,5,6,7,7,7-dodeca-fluoro-6-(trifluoromethyl)heptyl]oxirane:

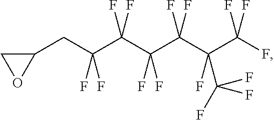 [SMILES: FC(F)(F)C(F)(C(F)(F)F)C(F)(F)C(F)(F)C(F)(F)C(F)(F)CC1CO1]

2,2,3,3,4,4,5,5,6,6,7,7,8,9,9,9-hexadecafluoro-8-(trifluoromethyl)nonyl]oxirane:

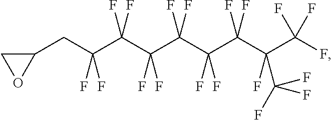 [SMILES: FC(F)(F)C(F)(C(F)(F)F)C(F)(F)C(F)(F)C(F)(F)C(F)(F)C(F)(F)C(F)(F)CC1CO1]

(2,2,3,3,4,4,5,5,6,6,7,7,8,8,9,9,10,10, 11,11,11-heneicosafluoroundecyl)oxirane:

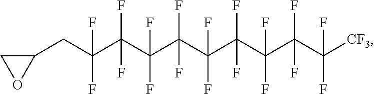 [SMILES: FC(F)(F)C(F)(F)C(F)(F)C(F)(F)C(F)(F)C(F)(F)C(F)(F)C(F)(F)C(F)(F)C(F)(F)CC1CO1]

and combinations thereof.

Whether one fluorinated monomer or a combination of fluorinated monomers is selected as the third monomer(s), the total amount of the fluorinated monomer(s) ranges from about from 0.5 mass % to about 4 mass %, based on a total solids content of the NIL resin composition. In one example, the total amount of the fluorinated monomer(s) is about 1.6 mass % based on the total solids content of the NIL resin composition.

The NIL resin composition also includes a photoinitiator. The photoinitiator is selected from the group consisting of a free radical photoinitiator, a cationic photoinitiator, and combinations thereof. Examples of the free radical initiator are selected from the group consisting of 1,1,2,2-tetraphenyl-1,2-ethanediol:

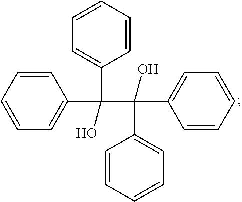 [SMILES: OC(c1ccccc1)(c1ccccc1)C(O)(c1ccccc1)c1ccccc1]

ethyl pyruvate:

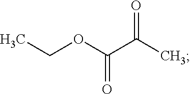

4-cyano-4-(phenylcarbonothioylthio)pentanoic acid:

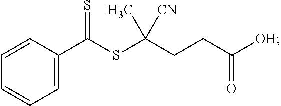 [SMILES: CC(C#N)(CCC(=O)O)SC(=S)c1ccccc1]

ethyl-3-methyl-2-oxobutanoate:

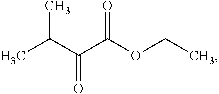

and combinations thereof. Examples of the cationic initiator are selected from the group consisting of bis-(4-methylphenyl)iodonium hexafluorophosphate:

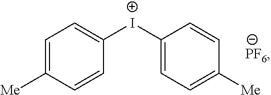

bis[4-(tert-butyl)phenyl]iodonium tetra(nonafluoro-tert-butoxy)aluminate:

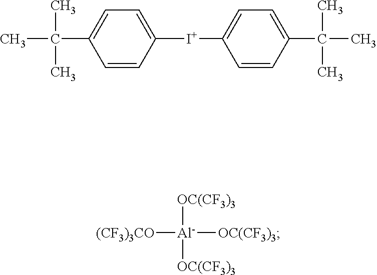

tris(4-((4-acetylphenyl)thio)phenyl)-sulfonium tetrakis(perfluoro-phenyl)borate (PAG 290):

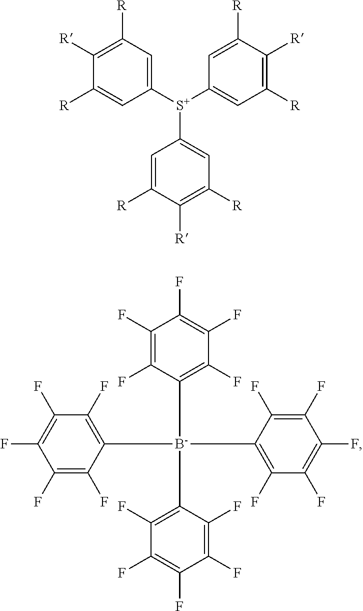

where R is

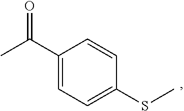

and combinations thereof.

In an example of the NIL resin composition, the photoinitiator (or each photoinitiator if a combination is used) is present in an amount ranging from about 1 mass % to about 26 mass %, based on a total solids content of the resin composition.

When a combination of the free radical initiator and the cationic initiator are used, the free radicals generated by the free radical initiator react with the cationic initiator/photoacid generator, which decomposes to generate a superacid, which, in turn, initiates the polymerization and crosslinking of the epoxy-group containing monomers. One example combination of the free radical initiator and the cationic initiator includes ethyl pyruvate and bis-(4-methylphenyl)iodonium hexafluorophosphate. In this particular example, the amount of ethyl pyruvate ranges from about 1 mass % to about 5 mass % and the amount of bis-(4-methylphenyl)iodonium hexafluorophosphate ranges from about 3 mass % to about 7 mass %.

In some examples, a combination of different cationic initiators is used. In these examples, it is believed that either or both of the cationic initiators behave as both superacid generators and as radical initiators. One example combination of cationic initiators includes bis-(4-methylphenyl)iodonium hexafluorophosphate and PAG 290. In this particular example, the amount of bis-(4-methylphenyl)iodonium hexafluorophosphate ranges from about 3 mass % to about 7 mass % and the amount of PAG 290 ranges from about 1 mass % to about 2 mass %.

Any example of the NIL resin composition disclosed herein may also include a solvent. The solvent may be added to the NIL resin composition to achieve a desired viscosity for the deposition technique being used to apply the resin composition. Examples of suitable solvents include propylene glycol monomethyl ether acetate (PGMEA), toluene, dimethyl sulfoxide (DMSO), tetrahydrofuran (THF), etc. In some examples, the solvent is PGMEA.

Once the solvent is added, the total solids concentration of the NIL resin composition may range from about 15 mass % to about 60 mass % (based on the total mass of the resin composition), and the amount of solvent may range from about 40 mass % to about 85 mass % (based on the mass of the resin composition). The upper limits of the total solids may be higher depending upon the respective solubility of the solid component(s) in the solvent that is selected. In some examples, the solid content is about 30% or less.

The NIL resin composition is ultraviolet light curable. In one example, a 365 nm UV light source may be used to cure the NIL resin composition.

To generate the NIL resin, the various components may be mixed together in any desirable order. One example of a method for making any example of the NIL resin compositions disclosed herein includes mixing the monomers (i.e., the two different epoxy silsesquioxane monomers, or the two different epoxy cyclosiloxane monomers, or the two different non-organosilicon epoxy monomers and the fluorinated monomer(s)), adding the initiator(s) to the monomer mixture, and dissolving the mixture with the solvent. Another example of a method for making any example of the NIL resin compositions disclosed herein includes mixing the monomers (i.e., the two different epoxy silsesquioxane monomers, or the two different epoxy cyclosiloxane monomers, or the two different non-organosilicon epoxy monomers, the fluorinated monomer(s)) and the initiator(s) to generate a mixture, and dissolving the mixture with the solvent. Still another example of a method for making any example of the NIL resin compositions disclosed herein includes mixing the fluorinated monomer(s) and the initiator(s) to generate a mixture, adding the other monomers (i.e., the two different epoxy silsesquioxane monomers, or the two different epoxy cyclosiloxane monomers, or the two different non-organosilicon epoxy monomers) to the mixture, and dissolving the mixture with the solvent.

Flow Cells and Method

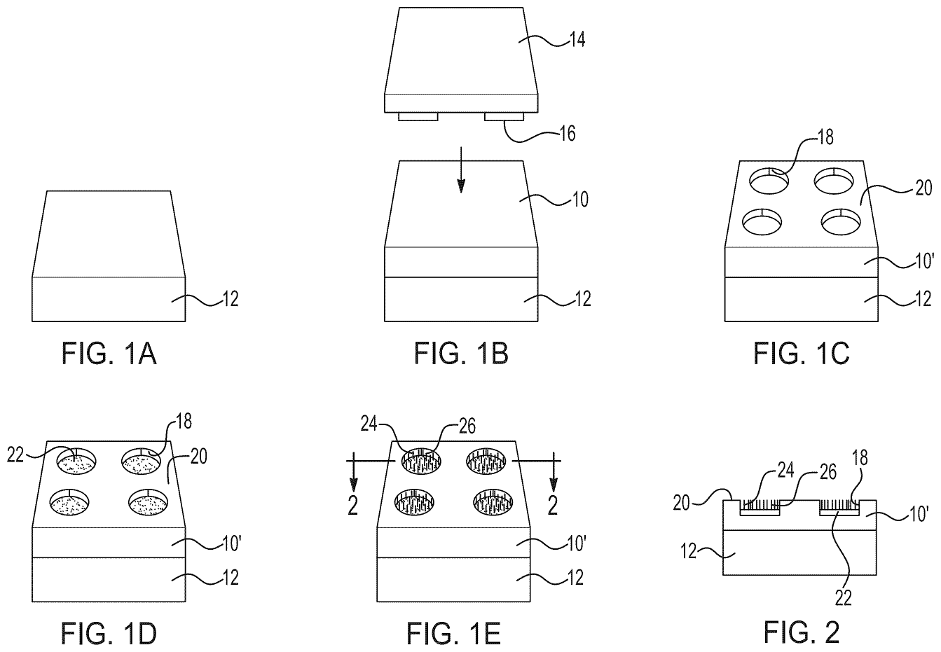

Any example of the NIL resin composition disclosed herein may be used in the formation of the flow cell. The NIL resin compositions may be patterned using nanoimprint lithography to generate the features of the flow cell. An example of the patterning method is shown schematically in FIG. 1A through FIG. 1C. The resulting flow cell surface (shown in FIG. 2) includes a substrate and a cured, patterned resin on the substrate, the cured, patterned resin including depressions separated by interstitial regions, and the cured, patterned resin including a cured form of the NIL resin composition disclosed herein. In other words, the cured, patterned resin is formed from an example of the NIL resin composition disclosed herein. Some examples of the method further include functionalizing the depressions for a particular application, such as sequencing. An example of the functionalization of the depressions is shown in FIG. 1D and FIG. 1E.

FIG. 1A depicts the substrate 12, and FIG. 1B depicts an example of the NIL resin composition 10 deposited on the substrate 12.

Examples of suitable substrates 12 include epoxy siloxane, glass, modified or functionalized glass (e.g., silanized glass), plastics (including acrylics, polystyrene and copolymers of styrene and other materials, polypropylene, polyethylene, polybutylene, polyurethanes, polytetrafluoroethylene (such as TEFLON® from Chemours), cyclic olefins/cyclo-olefin polymers (COP) (such as ZEONOR® from Zeon), polyimides, etc.), nylon (polyamides), ceramics/ceramic oxides, silica, fused silica, or silica-based materials, aluminum silicate, silicon and modified silicon (e.g., boron doped p+ silicon, silanized silicon), silicon nitride (Si₃N₄), silicon oxide (SiO₂), tantalum pentoxide (Ta₂O₅) or other tantalum oxide(s) (TaOₓ), hafnium oxide (HfO₂), carbon, metals, inorganic glasses, or the like. The substrate 12 may also be glass or silicon, with a coating layer of tantalum oxide or another ceramic oxide at the surface.

Some examples of the substrate 12 may have a surface-bound silane attached thereto, which can react with resin composition components to attach the cured resin composition 20 to the substrate 12. An example of an epoxy adhesion promoter is a norbornene silane, such as [(5-bicyclo[2.2.1]hept-2-enyl)ethyl]trimethoxysilane.

In an example, the substrate 12 may be a circular sheet, a panel, a wafer, a die etc. having a diameter ranging from about 2 mm to about 300 mm, e.g., from about 200 mm to about 300 mm, or may be a rectangular sheet, panel, wafer, die etc. having its largest dimension up to about 10 feet (˜3 meters). As one example, a die may have a width ranging from about 0.1 mm to about 10 mm. While example dimensions have been provided, it is to be understood that the substrate 12 may have any suitable dimensions.

The NIL resin composition 10 may be any of the examples described herein. The NIL resin composition 10 may be deposited on the substrate 12 using any suitable application technique, which may be manual or automated. As examples, the deposition of the NIL resin composition 10 may be performed using vapor deposition techniques, coating techniques, grafting techniques, or the like. Some specific examples include chemical vapor deposition (CVD), spray coating (e.g., ultrasonic spray coating), spin coating, dunk or dip coating, doctor blade coating, puddle dispensing, aerosol printing, screen printing, microcontact printing, inkjet printing, or the like. In one example, spin coating is used.

The deposited NIL resin composition 10 is then patterned, using any suitable patterning technique. In the example shown in FIG. 1B, nanoimprint lithography is used to pattern the NIL resin composition 10. After the NIL resin composition 10 is deposited, it may be softbaked to remove excess solvent and/or improve resin composition/substrate adhesion. When performed, the softbake may take place after the NIL resin composition 10 is deposited and before the working stamp 14 is positioned therein, and at a relatively low temperature, ranging from about 50° C. to about 150° C., for greater than 0 seconds to about 3 minutes. In an example, the softbake time ranges from about 30 seconds to about 2.5 minutes.

As illustrated in FIG. 1B, a nanoimprint lithography imprinting apparatus 14 (e.g., a mold or working stamp) is pressed or rolled against the layer of the NIL resin composition 10 to create an imprint on the NIL resin composition 10. The imprinting apparatus 14 includes a template of the desired pattern that is to be transferred to the NIL resin composition 10. Thus, the resin composition 10 is indented or perforated by the protrusions 16 of the working stamp 14. The protrusions 16 are a negative replica of the depressions or other features that are to be formed in the NIL resin composition 10. The NIL resin composition 10 may be then be cured with the working stamp 14 in place.

For the NIL resin compositions 10 disclosed herein, curing may be accomplished by exposing the nanoimprinted, deposited NIL resin composition 10 to incident light at a suitable energy dose (e.g., ranging from about 0.5 J to about 10 J) for 60 seconds or less. The incident light may be actinic radiation, such as ultraviolet (UV) radiation. In one example, the majority of the UV radiation emitted may have a wavelength of about 365 nm. More specifically, curing may be performed with a 365 nm ultraviolet (UV) light source; and the deposited NIL resin composition 10 is exposed to UV light for a time ranging from about 3 seconds to about 30 seconds. In this example, the 365 nm UV light source may be a light emitting diode (LED) having a 330 mW/cm² power output (measured at the sample level).

In the examples disclosed herein, the light energy exposure initiates polymerization and crosslinking of the monomers in the resin composition 10. With the effective extent of curing of the NIL resin compositions 10 set forth herein, the incident light exposure time may be 60 seconds or less. In some instances, the incident light exposure time may be 30 seconds or less. In still other instances, the incident light exposure time may be about 20 seconds. The curing process may include a single UV exposure stage or a single heating event.

After curing, the imprinting apparatus 14 may be removed. Upon release of the imprinting apparatus 14, topographic features, e.g., the depressions 18, are defined in the cured, resin composition 10′. As shown in FIG. 1C, the resin composition 10 having the depressions 18 defined therein is referred to as the cured, patterned resin 10′.

Due, at least in part, to the efficient photo polymerization of the resin compositions 10 disclosed herein, the method disclosed herein may not involve a post curing hardbake step in order to attain well-cured films. In some instances, it may be desirable to perform the post curing hardbake. It is to be understood that the working stamp 14 is released/detached before the hardbake (if performed), e.g., so that the working stamp 14 does not bond to the cured, patterned resin composition 10′. The duration of the hardbake may last from about 5 seconds to about 10 minutes at a temperature ranging from about 100° C. to about 300° C. Hardbaking may be performed, for example, to remove residual solvent(s) from the cured, patterned resin composition 10′, to further polymerization of some of the resin composition material(s) (and thus enhance the extent of curing), to improve adhesion and/or mechanical properties, and/or to further reduce the autofluorescence. Any of the heating devices set forth herein may be used for hardbaking.

The chemical make-up of the cured, patterned resin 10′ depends upon the NIL resin composition 10 that is used.

As shown in FIG. 1C, the cured, patterned resin 10′ includes the depressions 18 defined therein, and interstitial regions 20 separating adjacent depressions 18. In the examples disclosed herein, the depressions 18 become functionalized with a polymeric hydrogel 22 (FIG. 1D and FIG. 1E) and primers 24, 26 (FIG. 1E and FIG. 2), while portions of the interstitial regions 20 may be used for bonding but will not have the polymeric hydrogel 22 or the primer(s) 24, 26 thereon.

Many different layouts of the depressions 18 may be envisaged, including regular, repeating, and non-regular patterns. In an example, the depressions 18 are disposed in a hexagonal grid for close packing and improved density. Other layouts may include, for example, rectangular layouts (e.g., lines or trenches), triangular layouts, and so forth. In some examples, the layout or pattern can be an x-y format of depressions 18 that are in rows and columns. In some other examples, the layout or pattern can be a repeating arrangement of depressions 18 and/or interstitial regions 20. In still other examples, the layout or pattern can be a random arrangement of depressions 18 and/or interstitial regions 20. The pattern may include stripes, swirls, lines, triangles, rectangles, circles, arcs, checks, plaids, diagonals, arrows, squares, and/or cross-hatches. In an example, the depressions 18 are wells arranged in rows and columns, as shown in FIG. 1C.

The layout or pattern of the depressions 18 may be characterized with respect to the density of the depressions 18 (i.e., number of depressions 18) in a defined area. For example, the depressions 18 may be present at a density of approximately 2 million per mm². The density may be tuned to different densities including, for example, a density of at least about 100 per mm², about 1,000 per mm², about 0.1 million per mm², about 1 million per mm², about 2 million per mm², about 5 million per mm², about 10 million per mm², about 50 million per mm², or more, or less. It is to be further understood that the density of depressions 18 in the cured, patterned resin 10′ can be between one of the lower values and one of the upper values selected from the ranges above. As examples, a high density array may be characterized as having depressions 18 separated by less than about 100 nm, a medium density array may be characterized as having depressions 18 separated by about 400 nm to about 1 μm, and a low density array may be characterized as having depressions 18 separated by greater than about 1 μm. While example densities have been provided, it is to be understood that substrates with any suitable densities may be used.

The layout or pattern of the depressions 18 may also or alternatively be characterized in terms of the average pitch, i.e., the spacing from the center of the depression 18 to the center of an adjacent depression 18 (center-to-center spacing) or from the right edge of one depression 18 to the left edge of an adjacent depression 18 (edge-to-edge spacing). The pattern can be regular, such that the coefficient of variation around the average pitch is small, or the pattern can be non-regular in which case the coefficient of variation can be relatively large. In either case, the average pitch can be, for example, at least about 10 nm, about 50 nm, about 0.1 μm, about 0.5 μm, about 1 μm, about 5 μm, about 10 μm, about 100 μm, or more, or less. The average pitch for a particular pattern of depressions 18 can be between one of the lower values and one of the upper values selected from the ranges above. In an example, the depressions 18 have a pitch (center-to-center spacing) of about 1.5 μm. While example average pitch values have been provided, it is to be understood that other average pitch values may be used.

The size of each depression 18 may be characterized by its volume, opening area, depth, and/or diameter or length and width.

Each depression 18 can have any volume that is capable of confining a fluid. The minimum or maximum volume can be selected, for example, to accommodate the throughput (e.g., multiplexity), resolution, nucleotides, or analyte reactivity expected for downstream uses of the flow cell. For example, the volume can be at least about 1×10⁻³ μm³, about 1×10⁻² μm³, about 0.1 μm³, about 1 μm³, about 10 μm³, about 100 μm³, or more, or less. It is to be understood that the polymeric hydrogel 22 can fill all or part of the volume of a depression 18.

The area occupied by each depression opening can be selected based upon similar criteria as those set forth above for well volume. For example, the area for each depression opening can be at least about 1×10⁻³ μm², about 1×10⁻² μm², about 0.1 μm², about 1 μm², about 10 μm², about 100 μm², or more, or less. The area occupied by each depression opening can be greater than, less than or between the values specified above.

The depth of each depression 18 can be large enough to house some of the polymeric hydrogel 22. In an example, the depth may be about 0.1 μm, about 0.5 μm, about 1 μm, about 10 μm, about 100 μm, or more, or less. In some examples, the depth is about 0.4 μm. The depth of each depression 18 can be greater than, less than or between the values specified above.

In some instances, the diameter or length and width of each depression 18 can be about 50 nm, about 0.1 μm, about 0.5 μm, about 1 μm, about 10 μm, about 100 μm, or more, or less. The diameter or length and width of each depression 18 can be greater than, less than or between the values specified above.

After the resin composition 10 is patterned and cured, the cured, patterned resin 10′ may be treated to prepare the surface for application of a polymeric hydrogel 22.

In an example, the cured, patterned resin 10′ may be exposed to silanization, which attaches a silane or the silane derivative to the cured, patterned resin 10′. Silanization introduces the silane or the silane derivative across the surface, including in the depressions 18 (e.g., on the bottom surface and along the side walls) and on the interstitial regions 20.

Silanization may be accomplished using any silane or silane derivative. The selection of the silane or silane derivative may depend, in part, upon the functionalized molecule that is to be used to form the polymeric hydrogel 22 (shown in FIG. 2), as it may be desirable to form a covalent bond between the silane or silane derivative and the polymeric hydrogel 22. The method used to attach the silane or silane derivative to the cured, patterned resin 10′ may vary depending upon the silane or silane derivative that is being used. Several examples are set forth herein.

Examples of suitable silanization methods include vapor deposition, spin coating, or other deposition methods. Some examples of methods and materials that may be used to silanize the cured, patterned resin 10′ are described herein, although it is to be understood that other methods and materials may be used.

The attachment of the silane or silane derivative forms a pre-treated (e.g., silanized) cured, patterned resin 10′, which includes silanized depressions and silanized interstitial regions.

In other examples, the cured, patterned resin 10′ may not be exposed to silanization. Rather, the cured, patterned resin 10′ may be exposed to plasma ashing, and then the polymeric hydrogel 22 may be directly spin coated (or otherwise deposited) on the plasma ashed cured, patterned resin 10′. In this example, plasma ashing may generate surface-activating agent(s) (e.g., hydroxyl (C—OH or Si—OH) and/or carboxyl groups) that can adhere the polymeric hydrogel 22 to the cured, patterned resin 10′. In these examples, the polymeric hydrogel 22 is selected so that it reacts with the surface groups generated by plasma ashing.

In still other examples, the cured, patterned resin 10′ may include unreacted epoxy groups; and thus may not be exposed to silanization because the unreacted epoxy groups can react directly with amino functional groups of the polymeric hydrogel 22. In this example, plasma ashing may be performed, e.g., if it is desirable to clean the surface of potential contaminants.

The polymeric hydrogel 22 may then be applied to the pre-treated cured, patterned resin 10′ (as shown in FIG. 1D). The polymeric hydrogel 22 may be any gel material that can swell when liquid is taken up and can contract when liquid is removed, e.g., by drying. In an example, the polymeric hydrogel 22 includes an acrylamide copolymer. Some examples of the acrylamide copolymer are represented by the following structure (1):

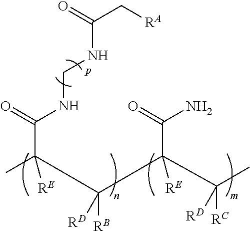

wherein:
R^{A} is selected from the group consisting of azido, optionally substituted amino, optionally substituted alkenyl, optionally substituted alkyne, halogen, optionally substituted hydrazone, optionally substituted hydrazine, carboxyl, hydroxy, optionally substituted tetrazole, optionally substituted tetrazine, nitrile oxide, nitrone, sulfate, and thiol;
R^{B} is H or optionally substituted alkyl;
R^{C}, R^{D}, and R^{E} are each independently selected from the group consisting of H and optionally substituted alkyl;
each of the —(CH₂)ₚ— can be optionally substituted;
p is an integer in the range of 1 to 50;
n is an integer in the range of 1 to 50,000; and
m is an integer in the range of 1 to 100,000.

One specific example of the acrylamide copolymer represented by structure (1) is poly(N-(5-azidoacetamidylpentyl)acrylamide-co-acrylamide, PAZAM.

One of ordinary skill in the art will recognize that the arrangement of the recurring “n” and “m” features in structure (I) are representative, and the monomeric subunits may be present in any order in the polymer structure (e.g., random, block, patterned, or a combination thereof).

The molecular weight of the acrylamide copolymer may range from about 5 kDa to about 1500 kDa or from about 10 kDa to about 1000 kDa, or may be, in a specific example, about 312 kDa.

In some examples, the acrylamide copolymer is a linear polymer. In some other examples, the acrylamide copolymer is a lightly cross-linked polymer.

In other examples, the polymeric hydrogel 22 may be a variation of structure (I). In one example, the acrylamide unit may be replaced with N,N-dimethylacrylamide

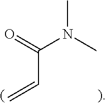

In this example, the acrylamide unit in structure (I) may be replaced with,

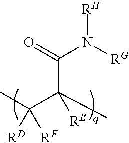

where R^{D}, R^{E}, and R^{F} are each H or a C1-C6 alkyl, and R^{G} and R^{H} are each a C1-C6 alkyl (instead of H as is the case with the acrylamide). In this example, q may be an integer in the range of 1 to 100,000. In another example, the N,N-dimethylacrylamide may be used in addition to the acrylamide unit. In this example, structure (I) may include

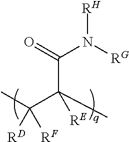

in addition to the recurring “n” and “m” features, where R^{D}, R^{E}, and R^{F} are each H or a C1-C6 alkyl, and R^{G} and R^{H} are each a C1-C6 alkyl. In this example, q may be an integer in the range of 1 to 100,000.

As another example of the polymeric hydrogel 22, the recurring “n” feature in structure (I) may be replaced with a monomer including a heterocyclic azido group having structure (II):

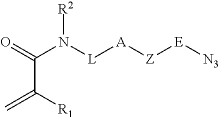

wherein R¹ is H or a C1-C6 alkyl; R₂ is H or a C1-C6 alkyl; L is a linker including a linear chain with 2 to 20 atoms selected from the group consisting of carbon, oxygen, and nitrogen and 10 optional substituents on the carbon and any nitrogen atoms in the chain; E is a linear chain including 1 to 4 atoms selected from the group consisting of carbon, oxygen and nitrogen, and optional substituents on the carbon and any nitrogen atoms in the chain; A is an N substituted amide with an H or a C1-C4 alkyl attached to the N; and Z is a nitrogen containing heterocycle. Examples of Z include 5 to 10 carbon-containing ring members present as a single cyclic structure or a fused structure. Some specific examples of Z include pyrrolidinyl, pyridinyl, or pyrimidinyl.

As still another example, the gel material may include a recurring unit of each of structure (III) and (IV):

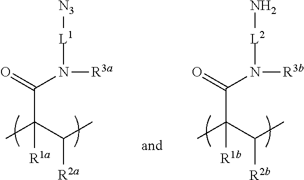

wherein each of R^{1a}, R^{2a}, R^{1b} and R^{2b} is independently selected from hydrogen, an optionally substituted alkyl or optionally substituted phenyl; each of R^{3a} and R^{3b} is independently selected from hydrogen, an optionally substituted alkyl, an optionally substituted phenyl, or an optionally substituted C7-C14 aralkyl; and each L¹ and L² is independently selected from an optionally substituted alkylene linker or an optionally substituted heteroalkylene linker.

In still another example, the acrylamide copolymer is formed using nitroxide mediated polymerization, and thus at least some of the copolymer chains have an alkoxyamine end group. In the copolymer chain, the term “alkoxyamine end group” refers to the dormant species —ONR₁R₂, where each of R₁ and R₂ may be the same or different, and may independently be a linear or branched alkyl, or a ring structure, and where the oxygen atom is attached to the rest of the copolymer chain. In some examples, the alkoxyamine may also be introduced into some of the recurring acrylamide monomers, e.g., at position R^{A} in structure (I). As such, in one example, structure (I) includes an alkoxyamine end group; and in another example, structure (I) includes an alkoxyamine end group and alkoxyamine groups in at least some of the side chains.

It is to be understood that other molecules may be used as the polymeric hydrogel 22, as long as they are capable of being functionalized with the desired chemistry, e.g., primers 24, 26. Some examples of suitable materials for the polymeric hydrogel 22 include functionalized silanes, such as norbornene silane, azido silane, alkyne functionalized silane, amine functionalized silane, maleimide silane, or any other silane having functional groups that can respectively attach the desired chemistry. Still other examples of suitable materials for the polymeric hydrogel 22 include those having a colloidal structure, such as agarose; or a polymer mesh structure, such as gelatin; or a cross-linked polymer structure, such as polyacrylamide polymers and copolymers, silane free acrylamide (SFA), or an azidolyzed version of SFA. Examples of suitable polyacrylamide polymers may be synthesized from acrylamide and an acrylic acid or an acrylic acid containing a vinyl group, or from monomers that form [2+2] photo-cycloaddition reactions. Still other examples of suitable materials for the polymeric hydrogel 22 include mixed copolymers of acrylamides and acrylates. A variety of polymer architectures containing acrylic monomers (e.g., acrylamides, acrylates etc.) may be utilized in the examples disclosed herein, such as branched polymers, including dendrimers (e.g., multi-arm or star polymers), and the like. For example, the monomers (e.g., acrylamide) may be incorporated, either randomly or in block, into the branches (arms) of a dendrimer.

The polymeric hydrogel 22 may be deposited on the surface of the pre-treated cured, patterned resin 10′ using spin coating, or dipping or dip coating, or flow of the functionalized molecule under positive or negative pressure, or another suitable technique. The polymeric hydrogel 22 may be present in a mixture. In an example, the mixture includes PAZAM in water or in an ethanol and water mixture.

After being coated, the polymeric hydrogel 22 may also be exposed to a curing process to form a coating of the polymeric hydrogel 22 across the entire patterned substrate (i.e., in depression(s) 18 and on interstitial region(s) 20). In an example, curing the polymeric hydrogel 22 may take place at a temperature ranging from room temperature (e.g., about 25° C.) to about 95° C. for a time ranging from about 1 millisecond to about several days. In another example, the time may range from 10 seconds to at least 24 hours. In still another example, the time may range from about 5 minutes to about 2 hours.

The attachment of the polymeric hydrogel 22 to the depressions 18 and interstitial regions 20 may be through covalent bonding. The covalent linking of the polymeric hydrogel 22 to the silanized or plasma ashed depressions is helpful for maintaining the polymeric hydrogel 22 in the depressions 18 throughout the lifetime of the ultimately formed flow cell during a variety of uses. The following are some examples of reactions that can take place between the silane or silane derivative and the polymeric hydrogel 22.

When the silane or silane derivative includes norbornene or a norbornene derivative as the unsaturated moiety, the norbornene or a norbornene derivative can: i) undergo a 1,3-dipolar cycloaddition reaction with an azide/azido group of PAZAM; ii) undergo a coupling reaction with a tetrazine group attached to PAZAM; undergo a cycloaddition reaction with a hydrazone group attached to PAZAM; undergo a photo-click reaction with a tetrazole group attached to PAZAM; or undergo a cycloaddition with a nitrile oxide group attached to PAZAM.

When the silane or silane derivative includes cyclooctyne or a cyclooctyne derivative as the unsaturated moiety, the cyclooctyne or cyclooctyne derivative can: i) undergo a strain-promoted azide-alkyne 1,3-cycloaddition (SPAAC) reaction with an azide/azido of PAZAM, or ii) undergo a strain-promoted alkyne-nitrile oxide cycloaddition reaction with a nitrile oxide group attached to PAZAM.

When the silane or silane derivative includes a bicyclononyne as the unsaturated moiety, the bicyclononyne can undergo similar SPAAC alkyne cycloaddition with azides or nitrile oxides attached to PAZAM due to the strain in the bicyclic ring system.

To form the polymeric hydrogel 22 in the depression(s) 18 and not on the interstitial region(s) 20 of the cured, patterned resin 10′, the polymeric hydrogel 22 may be polished off of the interstitial regions 20. The polishing process may be performed with a chemical slurry (including, e.g., an abrasive, a buffer, a chelating agent, a surfactant, and/or a dispersant) which can remove the polymeric hydrogel 22 from the interstitial regions 20 without deleteriously affecting the underlying cured, patterned resin 10′ and/or substrate 12 at those regions. Alternatively, polishing may be performed with a solution that does not include the abrasive particles. The chemical slurry may be used in a chemical mechanical polishing system. In this example, polishing head(s)/pad(s) or other polishing tool(s) is/are capable of polishing the polymeric hydrogel 22 from the interstitial regions 20 while leaving the polymeric hydrogel 22 in the depressions 18 and leaving the underlying cured, patterned resin 10′ at least substantially intact. As an example, the polishing head may be a Strasbaugh ViPRR II polishing head. In another example, polishing may be performed with a polishing pad and a solution without any abrasive. For example, the polish pad may be utilized with a solution free of the abrasive particle (e.g., a solution that does not include abrasive particles).

FIG. 1D depicts the polymeric hydrogel 22 in the depressions 18. A cleaning process may then be performed. This process may utilize a water bath and sonication. The water bath may be maintained at a relatively low temperature ranging from about 22° C. to about 30° C. The silanized, coated, and polished patterned substrate may also be spin dried, or dried via another suitable technique.

As shown in FIG. 1E, a grafting process is performed in order to graft primer(s) 24, 26 to the polymeric hydrogel 22 in the depression(s) 18. The primers 24, 26 may be any forward amplification primer and/or reverse amplification primer. In this example, the primers 24, 26 are two different primers.

It is desirable for the primers 24, 26 to be immobilized to the polymeric hydrogel 22. In some examples, immobilization may be by single point covalent attachment to the polymeric hydrogel 22 at the 5′ end of the respective primers 24, 26. Any suitable covalent attachment means known in the art may be used. In some examples, immobilization may be by strong non-covalent attachment (e.g., biotin-streptavidin).

Each of the primers 24, 26 has a universal sequence for capture and/or amplification purposes. As examples, the primers 24, 26 may include P5 and P7 primers, P15 and P7 primers, or any combination of the PA primers, the PB primers, the PC primers, and the PD primers set forth herein. As examples, the primers 24, 26 may include any two PA, PB, PC, and PD primers, or any combination of one PA primer and one PB, PC, or PD primer, or any combination of one PB primer and one PC or PD primer, or any combination of one PC primer and one PD primer.

Examples of P5 and P7 primers are used on the surface of commercial flow cells sold by Illumina Inc. for sequencing, for example, on HISEQ™, HISEQX™, MISEQ™, MISEQDX™, MINISEQ™, NEXTSEQ™, NEXTSEQDX™, NOVASEQ™, ISEQ™, GENOME ANALYZER™, and other instrument platforms. The P5 primer is:

### P5: 5→3′

### AATGATACGGCGACCACCGAGAUCTACAC (SEQ. ID. NO. 1)

The P7 primer may be any of the following:

P7 #1: 5′ → 3′
(SEQ. ID. NO. 2)
CAAGCAGAAGACGGCATACGAnAT
P7 #2: 5′ → 3′
(SEQ. ID. NO. 3)
CAAGCAGAAGACGGCATACnAGAT

where “n” is 8-oxoguanine in each of the sequences.
The P15 primer is:

P15: 5′ → 3′
(SEQ. ID. NO. 4)
AATGATACGGCGACCACCGAGAnCTACAC

where “n” is allyl-T (a thymine nucleotide analog having an allyl functionality).
The other primers (PA-PD) mentioned above include:

PA 5′ → 3′
(SEQ. ID. NO. 5)
GCTGGCACGTCCGAACGCTTCGTTAATCCGTTGAG
CPA (PA′) 5′ → 3′
(SEQ. ID. NO. 6)
CTCAACGGATTAACGAAGCGTTCGGACGTGCCAGC
PB 5′ → 3′
(SEQ. ID. NO. 7)
CGTCGTCTGCCATGGCGCTTCGGTGGATATGAACT
cPB (PB′) 5′ → 3′
(SEQ. ID. NO. 8)
AGTTCATATCCACCGAAGCGCCATGGCAGACGACG
PC 5′ → 3′
(SEQ. ID. NO. 9)
ACGGCCGCTAATATCAACGCGTCGAATCCGCAACT
cPC (PC′) 5′ → 3′
(SEQ. ID. NO. 10)
AGTTGCGGATTCGACGCGTTGATATTAGCGGCCGT
PD 5′ → 3′
(SEQ. ID. NO. 11)
GCCGCGTTACGTTAGCCGGACTATTCGATGCAGC
cPD (PD′) 5′ → 3′
(SEQ. ID. NO. 12)
GCTGCATCGAATAGTCCGGCTAACGTAACGCGGC

The P5 and P7 sequences illustrate the cleavage sites (e.g., U or “n”). While not shown in the example sequences for PA-PD, it is to be understood that any of these primers may include a cleavage site, such as uracil, 8-oxoguanine, allyl-T, etc. at any point in the strand. In any of the examples, the cleavage sites of the primers 24, 26 should be different from each other so that cleavage of the primers 24, 26 does not take place at the same time. Examples of suitable cleavage sites include enzymatically cleavable nucleobases or chemically cleavable nucleobases, modified nucleobases, or linkers (e.g., between nucleobases). The enzymatically cleavable nucleobase may be susceptible to cleavage by reaction with a glycosylase and an endonuclease, or with an exonuclease. One specific example of the cleavable nucleobase is deoxyuracil (dU), which can be targeted by the USER enzyme. Other abasic sites may also be used. Examples of the chemically cleavable nucleobases, modified nucleobases, or linkers include 8-oxoguanine, a vicinal diol, a disulfide, a silane, an azobenzene, a photocleavable group, allyl T (a thymine nucleotide analog having an allyl functionality), allyl ethers, or an azido functional ether.

Each of the primers 24, 26 disclosed herein may also include a polyT sequence at the 5′ end of the primer sequence. In some examples, the polyT region includes from 2 T bases to 20 T bases. As specific examples, the polyT region may include 3, 4, 5, 6, 7, or 10 T bases.

The 5′ end of each primer 24, 26 may also include a linker. Any linker that includes a terminal alkyne group or another suitable terminal functional group that can attach to the surface functional groups of the polymeric hydrogel 22 may be used. Examples of suitable terminal functional group including a tetrazine, an azido, an amino, an epoxy or glycidyl, a thiophosphate, a thiol, an aldehyde, a hydrazine, a phosphoramidite, a triazolinedione, or biotin. In one example, the primers 24, 26 are terminated with hexynyl. In some specific examples, a succinimidyl (NHS) ester terminated primer may be reacted with an amine at a surface of the polymeric hydrogel 22, an aldehyde terminated primer may be reacted with a hydrazine at a surface of the polymeric hydrogel 22, or an alkyne terminated primer may be reacted with an azide at a surface of the polymeric hydrogel 22, or an azide terminated primer may be reacted with an alkyne or DBCO (dibenzocyclooctyne) at a surface of the polymeric hydrogel 22, or an amino terminated primer may be reacted with an activated carboxylate group or NHS ester at a surface of the polymeric hydrogel 22, or a thiol terminated primer may be reacted with an alkylating reactant (e.g., iodoacetamine or maleimide) at a surface of the polymeric hydrogel 22, a phosphoramidite terminated primer may be reacted with a thioether at a surface of the polymeric hydrogel 22, or a biotin-modified primer may be reacted with streptavidin at a surface of the polymeric hydrogel 22.

In an example, grafting of the primers 24, 26 may be accomplished by flow through deposition (e.g., using a temporarily bound lid), dunk coating, spray coating, puddle dispensing, or by another suitable method that will attach the primer(s) 24, 26 to the polymeric hydrogel 22. Each of these example techniques may utilize a primer solution or mixture, which may include the primer(s) 24, 26, water, a buffer, and a catalyst.

Dunk coating may involve submerging the flow cell precursor (shown in FIG. 1D) into a series of temperature controlled baths. The baths may also be flow controlled and/or covered with a nitrogen blanket. The baths may include the primer solution or mixture. Throughout the various baths, the primer(s) 24, 26 will attach to the primer-grafting functional group(s) of the polymeric hydrogel 22 in at least some of the depression(s) 18. In an example, the flow cell precursor will be introduced into a first bath including the primer solution or mixture where a reaction takes place to attach the primer(s) 24, 26, and then moved to additional baths for washing. Movement from bath to bath may involve a robotic arm or may be performed manually. A drying system may also be used in dunk coating.

Spray coating may be accomplished by spraying the primer solution or mixture directly onto the flow cell precursor. The spray coated wafer may be incubated for a time ranging from about 4 minutes to about 60 minutes at a temperature ranging from about 0° C. to about 70° C. After incubation, the primer solution or mixture may be diluted and removed using, for example, a spin coater.

Puddle dispensing may be performed according to a pool and spin off method, and thus may be accomplished with a spin coater. The primer solution or mixture may be applied (manually or via an automated process) to the flow cell precursor. The applied primer solution or mixture may be applied to or spread across the entire surface of the flow cell precursor. The primer coated flow cell precursor may be incubated for a time ranging from about 2 minutes to about 60 minutes at a temperature ranging from about 0° C. to about 80° C. After incubation, the primer solution or mixture may be diluted and removed using, for example, the spin coater.

In other example, the primers 24, 26 may be pre-grafted to the polymeric hydrogel 22, and thus may be present in the depressions 18 once the polymeric hydrogel 22 is applied.

FIG. 1E and FIG. 2 illustrate an example of the flow cell surface after primer 24, 26 grafting or after a pre-grafted polymeric hydrogel is applied and removed from the interstitial regions 20.

The examples shown in FIG. 1E and FIG. 2 are examples of the flow cell surface without a lid or other flow cell surface bonded thereto. In an example, the lid may be bonded to at least a portion of the cured, patterned resin 10′, e.g., at some of the interstitial regions 20. The bond that is formed between the lid and the cured, patterned resin 10′ may be a chemical bond, or a mechanical bond (e.g., using a fastener, etc.).

The lid may be any material that is transparent to an excitation light that is directed toward the substrate 12 and the cured, patterned resin 10′. As examples, the lid may be glass (e.g., borosilicate, fused silica, etc.), plastic, or the like. A commercially available example of a suitable borosilicate glass is D 263®, available from Schott North America, Inc. Commercially available examples of suitable plastic materials, namely cyclo olefin polymers, are the ZEONOR® products available from Zeon Chemicals L.P.

The lid may be bonded to the cured, patterned resin 10′ using any suitable technique, such as laser bonding, diffusion bonding, anodic bonding, eutectic bonding, plasma activation bonding, glass frit bonding, or others methods known in the art. In an example, a spacer layer may be used to bond the lid to the cured, patterned resin 10′. The spacer layer may be any material that will seal at least some of the cured, patterned resin 10′ and the lid together. In some examples, the spacer layer can be a radiation-absorbing material that aids in bonding of the cured, patterned resin 10′ and the lid.

In other examples, two of the flow cells surfaces (one of which is shown in FIG. 1E and FIG. 2) may be bonded together so that the depressions 18 face a flow channel formed therebetween. The flow cells may be bonded at interstitial regions 20 using similar techniques and materials described herein for bonding the lid.

The flow cells may include a single flow channel or any desired number of flow channels that are fluidically separate from one another. This enables each flow channel to receive and process different samples at different times. In examples with multiple flow channels, it is to be understood that each flow channel includes functionalized depressions and respective inlets and outlets for introducing and removing reagents to/from the flow channel.

Methods for Using the Flow Cell

The flow cells disclosed herein may be used in a variety of sequencing approaches or technologies, including techniques often referred to as sequencing-by-synthesis (SBS), cyclic-array sequencing, sequencing-by-ligation, pyrosequencing, and so forth. With any of these techniques, since the polymeric hydrogel 22 and attached primer(s) 24, 26 are present in the depressions 18 and not on the interstitial regions 20, amplification will be confined to the depressions 18.

As one example, a sequencing by synthesis (SBS) reaction may be run on a system such as the HISEQ™, HISEQX™, MISEQ™, MISEQDX™, MINISEQ™, NOVASEQ™, ISEQ™, NEXTSEQDX™, or NEXTSEQ™ sequencer systems from Illumina (San Diego, CA). In SBS, extension of a nucleic acid primer (e.g., a sequencing primer) along a nucleic acid template (i.e., the sequencing template) is monitored to determine the sequence of nucleotides in the template. The underlying chemical process can be polymerization (e.g., catalyzed by a polymerase enzyme) or ligation (e.g., catalyzed by a ligase enzyme). In a particular polymerase-based SBS process, fluorescently labeled nucleotides are added to the sequencing primer (thereby extending the sequencing primer) in a template dependent fashion such that detection of the order and type of nucleotides added to the sequencing primer can be used to determine the sequence of the template.

Prior to sequencing, the capture and amplification primers 24, 26 can be exposed to a sequencing library, which is amplified using any suitable method, such as cluster generation.

In one example of cluster generation, the library fragments are copied from the hybridized primers 24, 26 by 3′ extension using a high-fidelity DNA polymerase. The original library fragments are denatured, leaving the copies immobilized. Isothermal bridge amplification may be used to amplify the immobilized copies. For example, the copied templates loop over to hybridize to an adjacent, complementary primer 24, 26 and a polymerase copies the copied templates to form double stranded bridges, which are denatured to form two single stranded strands. These two strands loop over and hybridize to adjacent, complementary primers 24, 26 and are extended again to form two new double stranded loops. The process is repeated on each template copy by cycles of isothermal denaturation and amplification to create dense clonal clusters. Each cluster of double stranded bridges is denatured. In an example, the reverse strand is removed by specific base cleavage, leaving forward template polynucleotide strands. Clustering results in the formation of several template polynucleotide strands in each of the depressions 18. This example of clustering is bridge amplification, and is one example of the amplification that may be performed. It is to be understood that other amplification techniques may be used, such as the exclusion amplification (Examp) workflow (Illumina Inc.).

A sequencing primer may be introduced that hybridizes to a complementary sequence on the template polynucleotide strand. This sequencing primer renders the template polynucleotide strand ready for sequencing. The 3′-ends of the templates and any flow cell-bound primers 24, 26 (not attached to the copy) may be blocked to prevent interference with the sequencing reaction, and in particular, to prevent undesirable priming.

To initiate sequencing, an incorporation mix may be added to the flow cell. In one example, the incorporation mix includes a liquid carrier, a polymerase, and fluorescently labeled nucleotides. The fluorescently labeled nucleotides may include a 3′ OH blocking group. When the incorporation mix is introduced into the flow cell, the fluid enters a flow channel and flows into the depressions 18 (where the template polynucleotide strands are present).

The fluorescently labeled nucleotides are added to the sequencing primer (thereby extending the sequencing primer) by the polymerase in a template dependent fashion such that detection of the order and type of nucleotides added to the sequencing primer can be used to determine the sequence of the template. More particularly, one of the nucleotides is incorporated, by a respective polymerase, into a nascent strand that extends the sequencing primer and that is complementary to the template polynucleotide strand. In other words, in at least some of the template polynucleotide strands across the flow cell, respective polymerases extend the hybridized sequencing primer by one of the nucleotides in the incorporation mix.

The incorporation of the nucleotides can be detected through an imaging event. During an imaging event, an illumination system (not shown) may provide an excitation light to the flow cell surface(s).

In some examples, the nucleotides can further include a reversible termination property (e.g., the 3′ OH blocking group) that terminates further primer extension once a nucleotide has been added to the sequencing primer. For example, a nucleotide analog having a reversible terminator moiety can be added to the sequencing primer such that subsequent extension cannot occur until a deblocking agent is delivered to remove the moiety. Thus, for examples that use reversible termination, a deblocking reagent can be delivered to the flow cell after detection occurs.

Wash(es) may take place between the various fluid delivery steps. The SBS cycle can then be repeated n times to extend the sequencing primer by n nucleotides, thereby detecting a sequence of length n.

In some examples, the forward strands may be sequenced and removed, and then reverse strands are constructed and sequenced as described herein.

While SBS has been described in detail, it is to be understood that the flow cells described herein may be utilized with other sequencing protocol, for genotyping, or in other chemical and/or biological applications.

While the examples described in FIG. 1A through FIG. 1E and FIG. 2 illustrate the use of the example NIL resin compositions 10 in the formation of a flow cell surface, it is to be understood that the NIL resin compositions 10 disclosed herein may be used in other applications. As one example, the NIL resin composition 10, 10′ may be used in any optically-based sequencing technique. As other examples, the NIL resin composition 10, 10′ may be used in planar waveguides, in complementary metal-oxide semiconductors (CMOS), etc.

To further illustrate the present disclosure, examples are given herein. It is to be understood that these examples are provided for illustrative purposes and are not to be construed as limiting the scope of the present disclosure.

### NON-LIMITING WORKING EXAMPLES

### Example 1

Three example resin compositions and two comparative resin compositions were prepared with the epoxy substituted cyclosiloxane monomers. The solids of the respective resins are shown in Table 1, with the amounts given a mass % per total mass of solids.

TABLE 1
Resin Solids

| Component | | | | | Comp. | Comp. |
|---|---|---|---|---|---|---|
| Type | Specific Component | Ex. 1 | Ex. 2 | Ex. 3 | Ex. 4 | Ex. 5 |
| Epoxy | epoxycyclohexyl | 60.3 | 60.3 | 60.3 | 60.3 | 60.3 |
| Monomer | tetramethylcyclotetrasiloxane | | | | | |
| | glycidyl cyclotetrasiloxane | 30.1 | 30.1 | 30.1 | 30.1 | 30.1 |
| Surface | Fluorinated monomer: | 0.8 | 1.6 | 3.2 | — | — |
| Additive | glycidyl 2,2,3,3,4,4,5,5- | | | | | |
| | octafluoropentyl ether | | | | | |
| | Polyacrylate: | — | — | — | — | 1.6 |
| | BYK ®-350 | | | | | |
| Photo- | bis-(4-methylphenyl) | 5 | 5 | 5 | 5 | 5 |
| initiator | iodonium | | | | | |
| | hexafluorophosphate | | | | | |
| | Ethyl pyruvate | 3 | 3 | 3 | 3 | 3 |

The example resins 1-3 included different amounts of the fluorinated monomer, glycidyl 2,2,3,3,4,4,5,5-octafluoropentyl ether. Comparative example resin 4 did not include any surface additive, and comparative example resin 5 included a polyacrylate surface additive (BYK®-350, available from BYK).

Propylene glycol methyl ether acetate (PGMEA) was added to each of the resin solids. The final concentration of each example resin and each comparative example resin was about 18 mass %.

Each of the example resin compositions 1-3 and the comparative resin compositions 4-5 was spin coated on a respective glass wafer. A used working stamp (previously used 25 times) was hand rolled on each of the coated wafers. The working stamp had a center-to-center pitch of 624 nm, and a feature height of 350 nm. The resin compositions were then exposed to UV curing under a 365 nm UV LED light source with a 330 mW/cm² power output measured at the sample level. Curing was performed for 30 seconds. After curing, the working stamp was released.

Atomic Force Microscopy (AFM) was used to examine the quality of the imprint by measuring the depth of each depression. The target depression depth was 350 nm. The AFM results are shown in Table 2.

TABLE 2
AFM Results

| Resin ID | Depression Depth (nm) |
|---|---|
| Ex. 1 | 362 |
| Ex. 2 | 360 |
| Ex. 3 | 351 |
| Comp. Ex. 4 | 356 |
| Comp. Ex. 5 | 362 |

These results demonstrate that the fluorinated monomer is compatible with the nanoimprinting process, and that it performs as well as the comparative polyacrylate surface additive.

### Example 2

One example resin composition and two comparative resin compositions were prepared with each of i) epoxy substituted cyclosiloxane monomers and ii) non-organosilicon epoxy monomers. The solids of the resins generated with the epoxy substituted cyclosiloxane monomers are shown in Table 3A and the solids of the resins generated with the non-organosilicon epoxy monomers are shown in Table 3B, with the amounts in each of these tables given as mass % per total mass of solids.

TABLE 3A
Resin Solids

| Component | | | Comp. | Comp. |
|---|---|---|---|---|
| Type | Specific Component | Ex. 6 | Ex. 7 | Ex. 8 |
| Epoxy | epoxycyclohexyl | 60.3 | 60.3 | 60.3 |
| Monomer | tetramethylcyclotetrasiloxane | | | |
| | glycidyl cyclotetrasiloxane | 30.1 | 30.1 | 30.1 |
| Surface | Fluorinated monomer: | 1.6 | — | — |
| Additive | glycidyl 2,2,3,3,4,4,5,5- | | | |
| | octafluoropentyl ether | | | |
| | Polyacrylate: BYK ®-350 | — | 1.6 | — |
| Photo- | bis-(4-methylphenyl) iodonium | 5 | 5 | 5 |
| initiator | hexafluorophosphate | | | |
| | Ethyl pyruvate | 3 | 3 | 3 |

TABLE 3B
Resin Solids

| Component | | | Comp. | Comp. |
|---|---|---|---|---|
| Type | Specific Component | Ex. 9 | Ex. 10 | Ex. 11 |
| Epoxy | 3,4-epoxycyclohexylmethyl | 46.2 | 46.2 | 46.2 |
| Monomer | 3,4- | | | |
| | epoxycyclohexanecarboxylate | | | |
| | Trimethylolpropane | 46.2 | 46.2 | 46.2 |
| | triglycidyl ether | | | |
| Surface | Fluorinated monomer: | 1.6 | — | — |
| Additive | glycidyl 2,2,3,3,4,4,5,5- | | | |
| | octafluoropentyl ether | | | |
| | Polyacrylate: BYK ®-350 | — | 1.6 | — |
| Photo- | bis-(4-methylphenyl) iodonium | 5 | 5 | 5 |
| initiator | hexafluorophosphate | | | |
| | PAG 290 | 1 | 1 | 1 |

Example resins 6 and 9 included 1.6 mass % of the fluorinated monomer, glycidyl 2,2,3,3,4,4,5,5-octafluoropentyl ether. Comparative example resins 8 and 11 did not include any surface additive, and comparative example resins 7 and 10 included the polyacrylate surface additive (BYK®-350, available from BYK).

Propylene glycol methyl ether acetate (PGMEA) was added to each of the resin solids. The final concentration of each example resin and each comparative example resin was about 18 mass %.

Each of the example resin compositions 6 and 9 and the comparative resin compositions 7, 8, 10, and 11 was spin coated on a respective glass wafer. A working stamp was hand rolled on each of the coated wafers. The working stamp had a center-to-center pitch of 624 nm. The resins composition were then exposed to UV curing under a 365 nm UV LED light source with a 330 mW/cm² power output measured at the sample level. Curing was performed for 30 seconds. After curing, the working stamp was released.

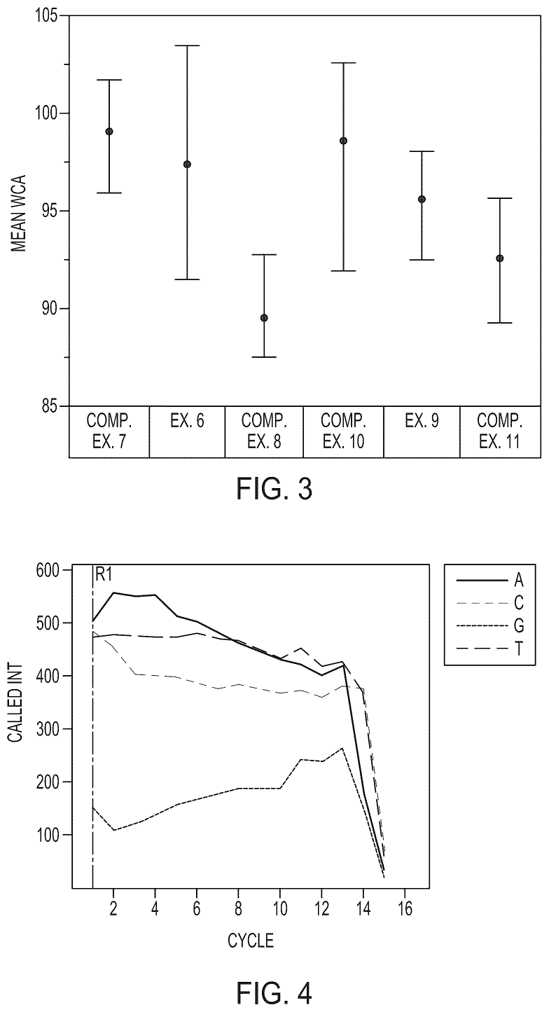

The water contact angle of the imprinted resins was measured using a Goniometer (which measures static water contact angles in air of sessile water drops on the surface), and the results are shown in FIG. 3 (where each imprints is identified by the resin used to generate it). As illustrated in FIG. 3, the fluorinated monomer (of example resins 6 and 9) increased the water contact angle of both of the example imprints in a similar manner to the polyacrylate surface additive (of comp. resins 7 and 10). These results demonstrate that the fluorinated monomer performs as well as the comparative polyacrylate surface additive in terms of decreasing the surface energy. From these results, it is believed that the fluorinated compound may also help to prolong the life of the working stamp.

### Example 3

Ex. resin 6 was used in this example. Ex. resin 6 was spin coated on a non-patterned glass die, and was exposed to UV curing under a 365 nm UV LED light source with a 330 mW/cm² power output measured at the sample level. Curing was performed for 30 seconds.

The coated glass die was ashed in air plasma at 595 W RF power for 30 seconds. The surface activated die was exposed to the neat chemical vapor of [(5-bicyclo[2.2.1]hept-2-enyl)ethyl]trimethoxysilane overnight at 60° C. to silanized the surface.

The silanized, coated glass die was bonded to a cover slip having fluidic channels engraved therein. Norland Optical Adhesive 81 was used for bonding, and the adhesive was UV cured for 9 minutes under a UV lamp with wide spectral emission and a power output of 3 mW measured at the sample level.

A 0.175 mass % N,N-dimethyl-acrylamide aqueous solution was introduced into the flow cell and incubated for 75 minutes at 70° C. This attached a hydrogel layer to the silanized surface of the coated glass die. P5 and P7 primers were then grafted onto the hydrogel layer from an 18 μM aqueous solution (incubated at 60° C. for 30 minutes).

The bonded flowcells were then exposed to clustering using a 0.67 pM PhiX library. The resulting templates were sequenced with violet and blue illumination, the optics settings of which are shown in Table 4.

TABLE 4
Optic Settings

| | Excitation | Collection | | Exposure |
|---|---|---|---|---|
| | Wavelength | Wavelength | Irradiance | Time |
| Channel | (nm) | (nm) | (W · cm⁻²) | (ms) |
| Violet | 402 | 418-447.5 | 71 | 500 |
| Blue | 464 | 482-520 | 236 | 300 |

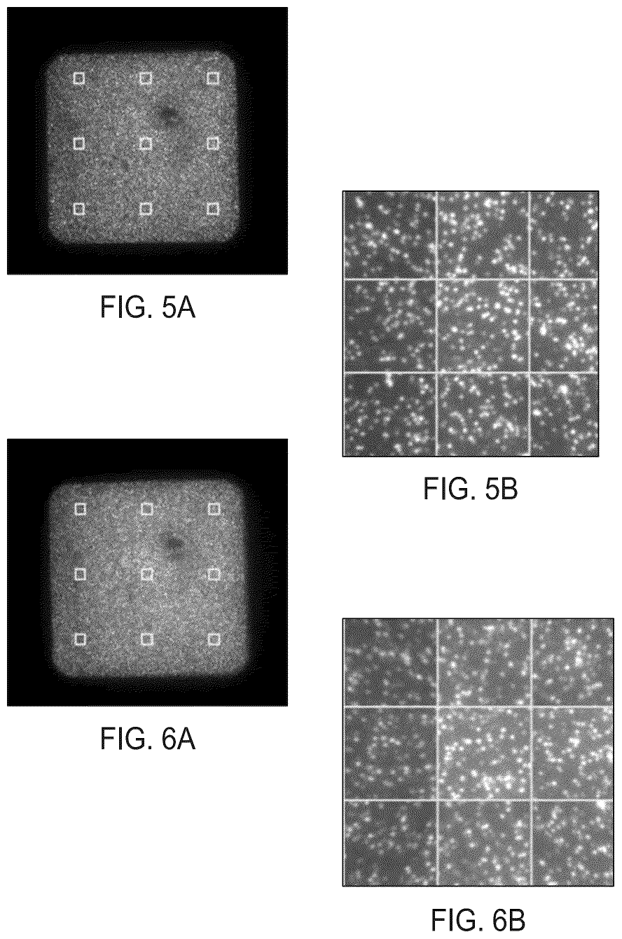

12 sequencing-by-synthesis (SBS) cycles were followed by removing the fluorescent dye from the 3′ blocking group in the 13^{th} cycle. The 14^{th} cycle consisted of an extra washing step by flushing a modified incorporation mix through the flowcell, which did not include any fully functional nucleotides (ffNs). In the 15^{th} cycle, the complementary strands were dehybridized from the clusters. After clustering on non-pattered flow cells, areas of the polymeric hydrogel may remain non-clustered. Cycles 13-15 were included as control runs to determine whether the ffNs bind to these off cluster areas of the substrate. FIG. 4 is a graph illustrating the signal intensity (Y axis) versus the cycle number (X axis). The results in FIG. 4 demonstrate that the ffNs do not bind to the surface (data for cycles 13-15) and are detected on the clusters (data for cycles 1-12). This data illustrates the unexpected result that the fluorinated monomer did not interfere with polymeric hydrogel attachment, primer grafting, template generation, or sequencing. Images taken on tile 3 of the flow cell in cycle 2 of sequencing are reproduced in FIG. 5A and FIG. 5B (a compilation of the highlighted areas of FIG. 5A) when blue illumination was used and in FIG. 6A and FIG. 6B (a compilation of the highlighted areas of FIG. 6A) when violet illumination was used. These results further demonstrate the unexpected compatibility of the fluorinated monomers with sequencing and altogether their viability as a levelling agent in the resin compositions disclosed herein.

### Additional Notes

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

While several examples have been described in detail, it is to be understood that the disclosed examples may be modified. Therefore, the foregoing description is to be considered non-limiting.

What is claimed is:

1. A nanoimprint lithography (NIL) resin composition, comprising:
a total of three monomers, wherein:
two of the three monomers are selected from the group consisting of:
two different epoxy substituted silsesquioxane monomers;
two different epoxy substituted cyclosiloxane monomers; and
two different non-organosilicon epoxy monomers; and
a third of the three monomers is a fluorinated monomer that is present in an amount ranging from about from 0.5 mass % to about 4 mass %, based on a total solids content of the NIL resin composition;
a photoinitiator; and
a solvent.

2. The NIL resin composition as defined in claim 1, wherein the fluorinated monomer is selected from the group consisting of 2,2′-(2,2,3,3,4,4,5,5-octafluorohexane-1,6-diyl)bis(oxirane), glycidyl 2,2,3,3,4,4,5,5-octafluoropentyl ether, glycidyl 2,2,3,3-tetrafluoropropyl ether, (2,2,3,3,4,4,5,5,6,6,7,7,8,8,9,9,9-heptadecafluorononyl)oxirane, (2,2,3,3,4,4,5,5,6,6,7,7,7-tridecafluoroheptyl)oxirane, 2,2,3,3,4,4,5,5,6,7,7,7-dodeca-fluoro-6-(trifluoromethyl)heptyl]oxirane, 2,2,3,3,4,4,5,5,6,6,7,7,8,9,9,9-hexadecafluoro-8-(trifluoromethyl)nonyl]oxirane, (2,2,3,3,4,4,5,5,6,6,7,7,8,8,9,9,10,10, 11,11,11-heneicosafluoroundecyl)oxirane, and combinations thereof.

3. The NIL resin composition as defined in claim 1, wherein:
the two of the three monomers are the two different epoxy substituted silsesquioxane monomers; and
the two different epoxy substituted silsesquioxane monomers consist of epoxycyclohexylethyl polysilsesquioxane and glycidyl polysilsesquioxane.

4. The NIL resin composition as defined in claim 3, wherein the two different epoxy substituted silsesquioxane monomers are present at a mass ratio ranging from about 3:7 to about 7:3.

5. The NIL resin composition as defined in claim 1, wherein:
the two of the three monomers are the two different epoxy substituted cyclosiloxane monomers; and
the two different epoxy substituted cyclosiloxane monomers consist of epoxycyclohexyl tetramethylcyclotetrasiloxane and glycidyl cyclotetrasiloxane.

6. The NIL resin composition as defined in claim 5, wherein the two different epoxy substituted cyclosiloxane monomers are present at a mass ratio ranging from about 3:7 to about 7:3.

7. The NIL resin composition as defined in claim 1, wherein:
the two of the three monomers are the two different non-organosilicon epoxy monomers; and
the two different non-organosilicon epoxy monomers are independently selected from the group consisting of trimethylolpropane triglycidyl ether, 3,4-epoxycyclohexylmethyl-3,4-epoxycyclo-hexanecarboxylate, bis((3,4-epoxycyclohexyl)methyl) adipate, 4-vinyl-1-cyclohexene 1,2-epoxide, vinylcyclohexene dioxide, 4,5-epoxytetrahydrophthalic acid diglycidylester, 1,2-epoxy-3-phenoxypropane, glycidyl methacrylate, 1,2-epoxyhexadecane, poly(ethylene glycol) diglycidylether, pentaerythritol glycidyl ether, diglycidyl 1,2-cyclohexanedicarboxylate, tetrahydrophthalic acid diglycidyl ester, 1,2-epoxy-3-phenoxypropane, and glycidyl methacrylate.

8. The NIL resin composition as defined in claim 7, wherein the two different non-organosilicon epoxy monomers are present at a mass ratio ranging from about 4:1 to about 1:4.

9. The NIL resin composition as defined in claim 1, wherein the photoinitiator is selected from the group consisting of a free radical photoinitiator, a cationic photoinitiator, and combinations thereof.

10. A flow cell, comprising:
a substrate;
a cured, patterned resin positioned over the substrate, the cured, patterned resin including imprinted depressions separated by interstitial regions, the cured, patterned resin including a cured form of a nanoimprint lithography (NIL) resin composition including:
a total of three monomers, wherein:
two of the three monomers are selected from the group consisting of:
two different epoxy silsesquioxane monomers;
two different epoxy cyclosiloxane monomers; and
two different non-organosilicon epoxy monomers; and
a third of the three monomers is a fluorinated monomer that is present in an amount ranging from about from 0.5 mass % to about 4 mass %, based on a total solids content of the NIL resin composition;
a photoinitiator; and
a solvent;
a polymeric hydrogel positioned within each of the depressions; and
a primer set attached to the polymeric hydrogel.

11. The flow cell as defined in claim 10, wherein the substrate is silanized glass or silanized silicon.

12. The flow cell as defined in claim 10, wherein the fluorinated monomer is selected from the group consisting of 2,2′-(2,2,3,3,4,4,5,5-octafluorohexane-1,6-diyl)bis(oxirane), glycidyl 2,2,3,3,4,4,5,5-octafluoropentyl ether, glycidyl 2,2,3,3-tetrafluoropropyl ether, (2,2,3,3,4,4,5,5,6,6,7,7,8,8,9,9,9-heptadecafluorononyl)oxirane, (2,2,3,3,4,4,5,5,6,6,7,7,7-tridecafluoroheptyl)oxirane, 2,2,3,3,4,4,5,5,6,7,7,7-dodeca-fluoro-6-(trifluoromethyl)heptyl]oxirane, 2,2,3,3,4,4,5,5,6,6,7,7,8,9,9,9-hexadecafluoro-8-(trifluoromethyl)nonyl]oxirane, (2,2,3,3,4,4,5,5,6,6,7,7,8,8,9,9,10,10, 11,11,11-heneicosafluoroundecyl)oxirane, and combinations thereof.

13. The flow cell as defined in claim 10, wherein:
the two of the three monomers are the two different epoxy substituted silsesquioxane monomers;
the two different epoxy substituted silsesquioxane monomers consist of epoxycyclohexylethyl polysilsesquioxane and glycidyl polysilsesquioxane; and
the two different epoxy substituted silsesquioxane monomers are present at a mass ratio ranging from about 3:7 to about 7:3.

14. The flow cell as defined in claim 10, wherein:
the two of the three monomers are the two different epoxy substituted cyclosiloxane monomers;
the two different epoxy substituted cyclosiloxane monomers consist of epoxycyclohexyl tetramethylcyclotetrasiloxane and glycidyl cyclotetrasiloxane; and
the two different epoxy substituted cyclosiloxane monomers are present at a mass ratio ranging from about 3:7 to about 7:3.

15. The flow cell as defined in claim 10, wherein:
the two of the three monomers are the two different non-organosilicon epoxy monomers;
the two different non-organosilicon epoxy monomers are independently selected from the group consisting of trimethylolpropane triglycidyl ether, 3,4-epoxycyclohexylmethyl-3,4-epoxycyclo-hexanecarboxylate, bis((3,4-epoxycyclohexyl)methyl) adipate, 4-vinyl-1-cyclohexene 1,2-epoxide, vinylcyclohexene dioxide, 4,5-epoxytetrahydrophthalic acid diglycidylester, 1,2-epoxy-3-phenoxypropane, glycidyl methacrylate, 1,2-epoxyhexadecane, poly(ethylene glycol) diglycidylether, pentaerythritol glycidyl ether, diglycidyl 1,2-cyclohexanedicarboxylate, tetrahydrophthalic acid diglycidyl ester, 1,2-epoxy-3-phenoxypropane, and glycidyl methacrylate; and
the two different non-organosilicon epoxy monomers are present at a mass ratio ranging from about 4:1 to about 1:4.

16. A method, comprising:
depositing a nanoimprint lithography (NIL) resin composition on a substrate, the NIL resin composition including:
a total of three monomers, wherein:
two of the three monomers are selected from the group consisting of:
two different epoxy silsesquioxane monomers;
two different epoxy cyclosiloxane monomers; and
two different non-organosilicon epoxy monomers; and
a third of the three monomers is a fluorinated monomer that is present in an amount ranging from about from 0.5 mass % to about 4 mass %, based on a total solids content of the NIL resin composition;
a photoinitiator; and
a solvent;
nanoimprinting the deposited NIL resin composition using a working stamp; and
curing the deposited NIL resin composition to form a cured, patterned resin.

17. The method as defined in claim 16, wherein the fluorinated monomer is selected from the group consisting of 2,2′-(2,2,3,3,4,4,5,5-octafluorohexane-1,6-diyl)bis(oxirane), glycidyl 2,2,3,3,4,4,5,5-octafluoropentyl ether, glycidyl 2,2,3,3-tetrafluoropropyl ether, (2,2,3,3,4,4,5,5,6,6,7,7,8,8,9,9,9-heptadecafluorononyl)oxirane, (2,2,3,3,4,4,5,5,6,6,7,7,7-tridecafluoroheptyl)oxirane, 2,2,3,3,4,4,5,5,6,7,7,7-dodeca-fluoro-6-(trifluoromethyl)heptyl]oxirane, 2,2,3,3,4,4,5,5,6,6,7,7,8,9,9,9-hexadecafluoro-8-(trifluoromethyl)nonyl]oxirane, (2,2,3,3,4,4,5,5,6,6,7,7,8,8,9,9,10,10, 11,11,11-heneicosafluoroundecyl)oxirane, and combinations thereof.

18. The method as defined in claim 16, wherein:
the two of the three monomers are the two different epoxy substituted silsesquioxane monomers;
the two different epoxy substituted silsesquioxane monomers consist of epoxycyclohexylethyl polysilsesquioxane and glycidyl polysilsesquioxane; and
the two different epoxy substituted silsesquioxane monomers are present at a mass ratio ranging from about 3:7 to about 7:3.

19. The method as defined in claim 16, wherein:
the two of the three monomers are the two different epoxy substituted cyclosiloxane monomers;
the two different epoxy substituted cyclosiloxane monomers consist of epoxycyclohexyl tetramethylcyclotetrasiloxane and glycidyl cyclotetrasiloxane; and
the two different epoxy substituted cyclosiloxane monomers are present at a mass ratio ranging from about 3:7 to about 7:3.

20. The method as defined in claim 16, wherein:
the two of the three monomers are the two different non-organosilicon epoxy monomers;
the two different non-organosilicon epoxy monomers are independently selected from the group consisting of trimethylolpropane triglycidyl ether, 3,4-epoxycyclohexylmethyl-3,4-epoxycyclo-hexanecarboxylate, bis((3,4-epoxycyclohexyl)methyl) adipate, 4-vinyl-1-cyclohexene 1,2-epoxide, vinylcyclohexene dioxide, 4,5-epoxytetrahydrophthalic acid diglycidylester, 1,2-epoxy-3-phenoxypropane, glycidyl methacrylate, 1,2-epoxyhexadecane, poly(ethylene glycol) diglycidylether, pentaerythritol glycidyl ether, diglycidyl 1,2-cyclohexanedicarboxylate, tetrahydrophthalic acid diglycidyl ester, 1,2-epoxy-3-phenoxypropane, and glycidyl methacrylate; and
the two different non-organosilicon epoxy monomers are present at a mass ratio ranging from about 4:1 to about 1:4.

21. The method as defined in claim 16, wherein:
curing is performed with a 365 nm ultraviolet light source; and
the deposited NIL resin composition is exposed to UV light for a time ranging from about 3 seconds to about 30 seconds.


SEQUENCE LISTING (12 sequences)

SEQ ID NO: 1 - DNA, 29 bp, synthetic construct
  source 1..29: mol_type = other DNA
  modified_base 23: mod_base = OTHER; note = Uracil
aatgatacggcgaccaccgagatctacac

SEQ ID NO: 2 - DNA, 24 bp, synthetic construct
  source 1..24: mol_type = other DNA
  modified_base 22: mod_base = OTHER; note = 8-oxoguanine
caagcagaagacggcatacganat

SEQ ID NO: 3 - DNA, 24 bp, synthetic construct
  source 1..24: mol_type = other DNA
  modified_base 20: mod_base = OTHER; note = 8-oxoguanine
caagcagaagacggcatacnagat

SEQ ID NO: 4 - DNA, 29 bp, synthetic construct
  source 1..29: mol_type = other DNA
  misc_difference 23: note = allyl-T
aatgatacggcgaccaccgaganctacac

SEQ ID NO: 5 - DNA, 35 bp, synthetic construct
  source 1..35: mol_type = other DNA
gctggcacgtccgaacgcttcgttaatccgttgag

SEQ ID NO: 6 - DNA, 35 bp, synthetic construct
  source 1..35: mol_type = other DNA
ctcaacggattaacgaagcgttcggacgtgccagc

SEQ ID NO: 7 - DNA, 35 bp, synthetic construct
  source 1..35: mol_type = other DNA
cgtcgtctgccatggcgcttcggtggatatgaact

SEQ ID NO: 8 - DNA, 35 bp, synthetic construct
  source 1..35: mol_type = other DNA
agttcatatccaccgaagcgccatggcagacgacg

SEQ ID NO: 9 - DNA, 35 bp, synthetic construct
  source 1..35: mol_type = other DNA
acggccgctaatatcaacgcgtcgaatccgcaact

SEQ ID NO: 10 - DNA, 35 bp, synthetic construct
  source 1..35: mol_type = other DNA
agttgcggattcgacgcgttgatattagcggccgt

SEQ ID NO: 11 - DNA, 34 bp, synthetic construct
  source 1..34: mol_type = other DNA
gccgcgttacgttagccggactattcgatgcagc

SEQ ID NO: 12 - DNA, 34 bp, synthetic construct
  source 1..34: mol_type = other DNA
gctgcatcgaatagtccggctaacgtaacgcggc